(19) United States
(12) Patent Application Publication
(10) Pub. No.: US 2025/0096173 A1
(43) Pub. Date: Mar. 20, 2025

(54) SHEET FOR FORMING FIRST PROTECTIVE MEMBRANE, METHOD FOR MANUFACTURING SEMICONDUCTOR DEVICE, AND USE OF SHEET

(71) Applicant: LINTEC CORPORATION, Tokyo (JP)

(72) Inventors: Tomotaka MORISHITA, Tokyo (JP); Keisuke SHINOMIYA, Tokyo (JP)

(21) Appl. No.: 18/727,447

(22) PCT Filed: Dec. 20, 2022
(86) PCT No.: PCT/JP2022/046800

§ 371 Date: Jul. 9, 2024

(30) Foreign Application Priority Data
Jan. 12, 2022 (JP) 2022-003126

(51) Int. Cl. H01L 23/00; H01L 21/78

(52) U.S. Cl. CPC H01L 24/11; H01L 21/78; H01L 2224/11019

(57) ABSTRACT

A first protective membrane forming sheet for forming a first protective membrane on at least a surface of a semiconductor wafer having a bump, the first protective membrane forming sheet including a first base material, a buffer layer, an intermediate release layer, and a first protective membrane forming film stacked in this order in a thickness direction thereof, wherein the intermediate release layer contains an ethylene-vinyl acetate copolymer.

### TECHNICAL FIELD

The present invention relates to a first protective membrane forming sheet, a method for manufacturing a semiconductor device, and use of the sheet.

The present application claims priority from the Japanese Patent Application No. 2022-003126, filed in Japan on Jan. 12, 2022, the contents of which are incorporated herein by reference.

### BACKGROUND ART

When mounting a multi-pin LSI package used in MPUs, gate arrays, and the like on a printed wiring board, a known flip-chip mounting method has been adopted. In this method, a semiconductor chip in which protruding electrodes (hereinafter, in the present specification, referred to as “bumps”) made of eutectic solder, high temperature solder, gold, and the like are formed on the bond pad portion is used, and the bumps of the chip are faced with and brought into contact with the corresponding terminal portions on a chip mounting substrate in a “face-down” manner and subjected to melt bonding or diffusion bonding.

The semiconductor chip used in this mounting method is produced, for example, from a semiconductor wafer having a circuit surface on which a bump is formed (in other words, a bump-formed surface), by grinding or dicing a surface of the semiconductor wafer opposite to the bump-formed surface, and dividing the semiconductor wafer into pieces. In a process of producing such a semiconductor chip, for example, for the purpose of protecting the bump-formed surface and the bumps of the semiconductor wafer, a curable protective membrane forming film is attached to the bump-formed surface, and the film is cured to form a protective membrane on the bump-formed surface. In the present specification, such a protective membrane forming film and a protective membrane may be referred to as “first protective membrane forming film” and “first protective membrane”, respectively. At this time, it is necessary that the bump on the bump-formed surface penetrates the protective membrane forming film (first protective membrane forming film) and the top portion of the bump protrudes from the protective membrane forming film.

FIG. 1 is a sectional view schematically illustrating an example of a state where the protective membrane forming film remains on the upper portion of the bump, contrary to such a case. A known protective membrane forming film 82 is attached to a surface (bump-formed surface) 9a of a wafer 9 having a bump 91 illustrated in the drawing, but a top portion 9101 of the bump 91 does not protrude from the protective membrane forming film 82, and the protective membrane forming film 82 remains on an upper portions 910 of the bump 91. Here, an example in which an entire surface 91a of the bump 91 is covered with the protective membrane forming film 82 is illustrated, but this is an example of a remaining state of the protective membrane forming film 82, and for example, in the upper portion 910 of the bump 91, a part of the surface 91a may be exposed without being covered with the protective membrane forming film 82. The semiconductor wafer in which the protective membrane forming film remains on the bump like this cannot be used for flip-chip mounting as it is.

On the other hand, when the protective membrane forming film is attached to the bump-formed surface, a protective membrane forming sheet in which the protective membrane forming film, a pressure sensitive adhesive layer, and a base material are stacked in this order may be used. In the present specification, such a protective membrane forming sheet may be referred to as “first protective membrane forming sheet”. In this case, the pressure sensitive adhesive layer and the base material are removed from the protective membrane forming film after being attached to the bump-formed surface, and the protective membrane forming film is cured.

As such a protective membrane forming sheet, there is disclosed a protective membrane forming sheet including a base material, an energy ray-curable pressure sensitive adhesive layer, a buffer layer, and a curable protective membrane forming film in this order, in which the shear storage modulus of the protective membrane forming film before curing and the tensile storage modulus of the pressure sensitive adhesive layer after energy ray curing are set to specific ranges (see Patent Literature 1). This protective membrane forming sheet (first protective membrane forming sheet) makes it possible to easily remove the pressure sensitive adhesive layer and the base material from the protective membrane forming film (first protective membrane forming film) after being attached to the bump-formed surface, and a protective membrane (first protective membrane) can be satisfactorily formed on the bump-formed surface. Further, when the protective membrane forming film is attached to the bump-formed surface, the effect of protecting the bump improves because of the buffer layer.

### CITATION LIST

### Patent Literature

Patent Literature 1: WO 2020/189447

### SUMMARY OF INVENTION

### Technical Problem

On the other hand, in recent years, to efficiently form the protective membrane on the bump-formed surface, it has been studied to attach the protective membrane forming film in the sheet for forming a protective membrane to the bump-formed surface at a higher speed than before. However, when the protective membrane forming film is attached to the bump-formed surface, it is difficult not only to attach the protective membrane forming film itself but also to cause the top portion of the bump to protrude from the protective membrane forming film. Even though the top portion of the bump protrudes, the protective membrane forming film tends to remain on the upper portion including the top portion of the bump. When the protective membrane forming film remains on the upper portion of the bump like this, the protective membrane adheres to the upper portion of the bump as it is, and thus the semiconductor chip is not suitable for flip-chip mounting. Regarding this, the protective membrane forming sheet disclosed in Patent Literature 1 is excellent in suitability for attaching the protective membrane forming film to a bump-formed surface, but it is not intended for high-speed attachment.

An object of the present invention is to provide a protective membrane forming sheet including a protective membrane forming film for forming a protective membrane on a surface of a semiconductor wafer having a bump. The protective membrane forming film in the protective membrane forming sheet allows a top portion of the bump to protrude from the protective membrane forming film and prevents the protective membrane forming film from remaining on an upper portion including the top portion of the bump, even when the protective membrane forming sheet is attached to the surface of the semiconductor wafer at a high speed.

### Solution to Problem

To solve the issues described above, the present invention adopts the following configuration.

[1] A first protective membrane forming sheet for forming a first protective membrane on at least a surface of a semiconductor wafer having a bump, the first protective membrane forming sheet including a first base material, a buffer layer, an intermediate release layer, and a first protective membrane forming film stacked in this order in a thickness direction thereof, wherein the intermediate release layer contains an ethylene-vinyl acetate copolymer.

[2] The first protective membrane forming sheet according to [1], wherein in the ethylene-vinyl acetate copolymer, a proportion of an amount of a constitutional unit derived from vinyl acetate to a total amount of constitutional units is from 16 to 40 mass %.

[3] The first protective membrane forming sheet according to [1] or [2], wherein the ethylene-vinyl acetate copolymer has a weight average molecular weight of 200000 or less.

[4] A method for manufacturing a semiconductor device using the first protective membrane forming sheet according to any one of [1] to [3], the method including:
attaching the first protective membrane forming film in the first protective membrane forming sheet to a surface of a semiconductor wafer having a bump such that a top portion of the bump protrudes from the first protective membrane forming film, to provide the first protective membrane forming sheet on the semiconductor wafer;
forming of a first protective membrane by
removing a layer other than the first protective membrane forming film from the first protective membrane forming film in the first protective membrane forming sheet after the attaching of the first protective membrane forming film, and further
in case where the first protective membrane forming film is curable, curing the first protective membrane forming film to form a first protective membrane, or
in case where the first protective membrane forming film is non-curable, handling, as the first protective membrane, the first protective membrane after the layer other than the first protective membrane forming film has been removed to form the first protective membrane on the surface having the bump;
dividing the semiconductor wafer after the forming of the first protective membrane forming to produce a semiconductor chip;
cutting the first protective membrane after the forming of the first protective membrane; and
mounting the semiconductor chip with the first protective membrane to a substrate by flip-chip connecting the semiconductor chip with the first protective membrane to the substrate at a top portion of the bump, the semiconductor chip with the first protective membrane including the semiconductor chip produced after the dividing and the cutting, and the first protective membrane provided on a surface of the semiconductor chip having the bump, wherein the top portion of the bump protrudes from the first protective membrane.

[5] The method for manufacturing a semiconductor device according to [4], wherein in the attaching of the first protective membrane forming film, the first protective membrane forming film is attached to the surface of the semiconductor wafer having the bump at an attachment speed of 4 mm/s or more.

[6] A use of a sheet for forming a first protective membrane on at least a surface of a semiconductor wafer, the surface having a bump, the sheet including a first base material, a buffer layer, an intermediate release layer, and a first protective membrane forming film stacked in this order in a thickness direction of thereof, wherein the intermediate release layer contains an ethylene-vinyl acetate copolymer.

### Advantageous Effects of Invention

The present invention provides a protective membrane forming sheet including a protective membrane forming film for forming a protective membrane on a surface of a semiconductor wafer having a bump. The protective membrane forming film in the protective membrane forming sheet allows a top portion of the bump to protrude from the protective membrane forming film and prevents the protective membrane forming film from remaining on an upper portion including the top portion of the bump, even when the protective membrane forming sheet is attached to the surface of the semiconductor wafer at a high speed.

### BRIEF DESCRIPTION OF DRAWINGS

FIG. 1 is a cross-sectional view schematically illustrating an example of a state where a protective membrane forming film remains on an upper portion of a bump.

FIG. 2 is a cross-sectional view schematically illustrating an example of a sheet for forming a first protective membrane according to a first embodiment of the present invention.

FIG. 3A is a cross-sectional view for schematically describing an example of a method for manufacturing a semiconductor device in a case of using the first protective membrane forming sheet illustrated in FIG. 2.

FIG. 3B is a cross-sectional view for schematically describing the example of the method for manufacturing a semiconductor device in a case of using the first protective membrane forming sheet illustrated in FIG. 2.

FIG. 3C is a cross-sectional view for schematically describing the example of the method for manufacturing a semiconductor device in a case of using the first protective membrane forming sheet illustrated in FIG. 2.

FIG. 3D is a cross-sectional view for schematically describing the example of the method for manufacturing a semiconductor device in a case of using the first protective membrane forming sheet illustrated in FIG. 2.

FIG. 3E is a cross-sectional view for schematically describing the example of the method for manufacturing a semiconductor device in a case of using the first protective membrane forming sheet illustrated in FIG. 2.

FIG. 4A is a cross-sectional view for schematically describing another example of the method for manufacturing a semiconductor device in a case of using the first protective membrane forming sheet illustrated in FIG. 2.

FIG. 4B is a cross-sectional view for schematically describing the another example of the method for manufacturing a semiconductor device in a case of using the first protective membrane forming sheet illustrated in FIG. 2.

FIG. 4C is a cross-sectional view for schematically describing the another example of the method for manufacturing a semiconductor device in a case of using the first protective membrane forming sheet illustrated in FIG. 2.

FIG. 4D is a cross-sectional view for schematically describing the another example of the method for manufacturing a semiconductor device in a case of using the first protective membrane forming sheet illustrated in FIG. 2.

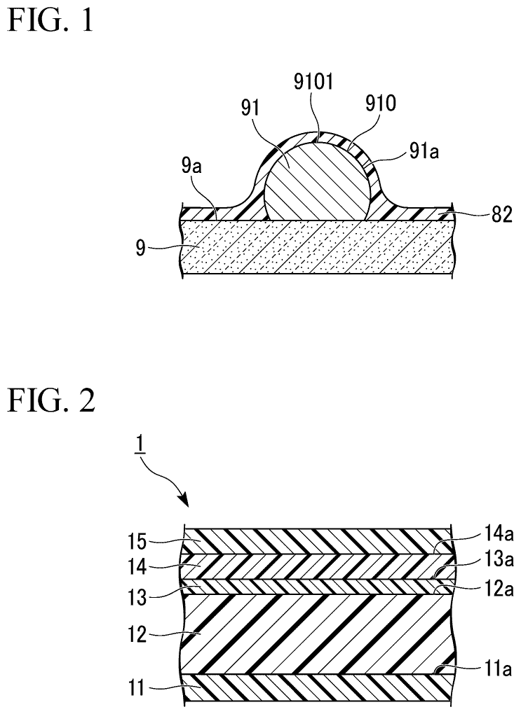

### DESCRIPTION OF EMBODIMENTS

### First Protective Membrane Forming Sheet

A first protective membrane forming sheet according to one embodiment of the present invention is a first protective membrane forming sheet for forming a first protective membrane on at least a surface of a semiconductor wafer having a bump, the first protective membrane forming sheet including a first base material, a buffer layer, an intermediate release layer, and a first protective membrane forming film stacked in this order in a thickness direction thereof, wherein the intermediate release layer contains an ethylene-vinyl acetate copolymer.

The first protective membrane forming sheet of the present embodiment, having such a configuration, can cause a top portion of a bump to protrude from the protective membrane forming film and can prevent the protective membrane forming film from remaining on an upper portion of the bump including the top portion of the bump because of the protective membrane forming film in the first protective membrane forming sheet even when the first protective membrane forming sheet is attached to a surface of a semiconductor wafer having the bump at a high speed.

In the present specification, in both the semiconductor wafer and the semiconductor chip, the surface having the bump may be referred to as “bump-formed surface”. The surface of the semiconductor wafer and the semiconductor chip opposite to the bump-formed surface may be referred to as “back surface”.

In the present specification, the protective membrane provided on the surface (that is, the back surface) opposite to the bump-formed surface of the semiconductor wafer or the semiconductor chip is referred to as “second protective membrane”.

To provide the second protective membrane on the surface (back surface) opposite to the bump-formed surface of the semiconductor wafer or the semiconductor chip, a second protective membrane forming sheet including a second protective membrane forming film for forming the second protective membrane is used. An example of the second protective membrane forming sheet includes a dicing sheet and a second protective membrane forming film provided on the dicing sheet. When the dicing sheet includes the same material as the first base material, this base material is referred to as “second base material”.

With the first protective membrane forming sheet of the present embodiment, the first protective membrane can be formed not only on the bump-formed surface of a semiconductor chip but also on a side surface of the semiconductor chip as described later. That is, the first protective membrane forming sheet of the present embodiment can be used as a sheet for forming the first protective membrane at least on the bump-formed surface of a semiconductor wafer.

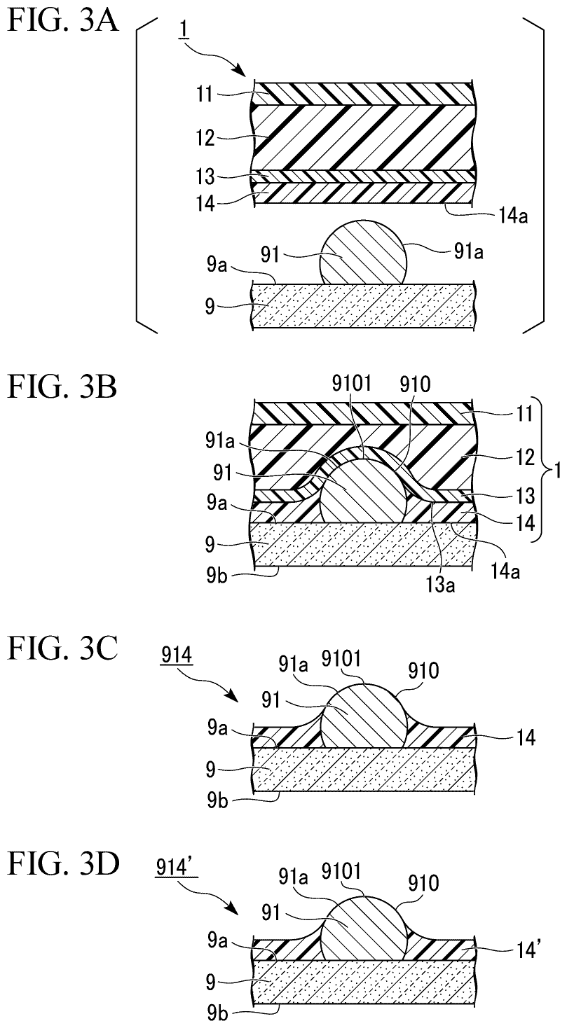

FIG. 2 is a cross-sectional view schematically illustrating an example of the first protective membrane forming sheet of the present embodiment.

In figures used in the following descriptions, a main part may be enlarged for convenience to facilitate understanding of features of the present invention, and a dimension ratio or the like of each component is not necessarily identical to the actual one.

The first protective membrane forming sheet 1 illustrated here includes a first base material 11, a buffer layer 12 provided on one surface 11a of the first base material 11, an intermediate release layer 13 provided on a surface 12a of the buffer layer 12 on the side opposite to the first base material 11 side, and a first protective membrane forming film 14 provided on a surface 13a of the intermediate release layer 13 on the side opposite to the buffer layer 12 side (may be referred to as “first surface” in the present specification). That is, the first protective membrane forming sheet 1 has a configuration in which the first base material 11, the buffer layer 12, the intermediate release layer 13, and the first protective membrane forming film 14 are stacked in this order in a thickness direction of these materials.

The first protective membrane forming sheet 1 further includes a release film 15 provided on a surface 14a of the first protective membrane forming film 14 on the side opposite to the intermediate release layer 13 side (may be referred to as “first surface” in the present specification).

In the first protective membrane forming sheet 1, the intermediate release layer 13 contains an ethylene-vinyl acetate copolymer (may be referred to as “EVA” in the present specification).

The release film 15 is not particularly limited and may be a known release film.

In the first protective membrane forming sheet 1, the release film 15 is an optional component, and the first protective membrane forming sheet 1 need not include the release film 15.

The first protective membrane forming sheet of the present embodiment is not limited to the one illustrated in FIG. 2, and a part of the configuration may be changed, deleted, or added in the one illustrated in FIG. 2 within a range in which the effect of the present invention is not impaired.

For example, the first protective membrane forming sheet of the present embodiment may further include another layer that does not correspond to any of the first base material, the buffer layer, the intermediate release layer, the first protective membrane forming film, and the release film. However, in the first protective membrane forming sheet not provided with a release film, it is preferable that the first protective membrane forming film be the outermost layer on one side, that is, a layer disposed on the outermost side in the stacking direction of each layer. In the first protective membrane forming sheet of the present embodiment, it is preferable that the first base material and the buffer layer be provided in direct contact, the buffer layer and the intermediate release layer be provided in direct contact, and the intermediate release layer and the first protective membrane forming film be provided in direct contact.

Next, each layer constituting the first protective membrane forming sheet of the present embodiment will be described.

### First Protective Membrane Forming Film

The first protective membrane forming film may be curable or non-curable. For example, the first protective membrane forming film may function as the first protective membrane by being cured, or may function as the first protective membrane in an uncured state.

The first protective membrane forming film that is curable may be either thermosetting or energy ray-curable, or may have both thermosetting and energy ray-curable properties.

The first protective membrane forming film is preferably curable from the viewpoint of being capable of forming a first protective membrane having a higher protective ability.

In the present specification, “energy rays” means electromagnetic waves or charged particle beams having energy quanta. Examples of the energy rays include ultraviolet light, radioactive rays, and electron beams. The ultraviolet light can be irradiated by using, for example, a high-pressure mercury lamp, a fusion lamp, a xenon lamp, a black light, or an LED lamp as an ultraviolet ray source. The electron beam can be generated by an electron beam accelerator or the like and irradiated.

Herein, “energy ray-curable” refers to a property of curing by irradiation with an energy ray, and “non-energy ray-curable” means a property of not curing even when the composition is irradiated with an energy ray.

In the present specification, the term “non-curable” means a property of not being cured by any means such as heating or irradiation with energy rays.

The first protective membrane forming film contains a resin component, and may contain a component other than the resin component, but it need not contain a component other than the resin component.

The first protective membrane forming film is soft and has high followability to an uneven surface such as a bump-formed surface of a semiconductor wafer. As a result, the first protective membrane forming film and the first protective membrane exhibit high adhesion to an uneven surface such as a bump-formed surface of a semiconductor wafer, and the first protective membrane exhibits high adhesion to an uneven surface such as a bump-formed surface of a semiconductor chip.

When the first protective membrane forming film in the first protective membrane forming sheet of the present embodiment is attached to a bump-formed surface of a semiconductor wafer while being heated, the bump on the bump-formed surface penetrates the first protective membrane forming film, and the top portion of the bump protrudes from the first protective membrane forming film. Then, the softened first protective membrane forming film spreads between bumps in such a manner as to cover the bumps, is in close contact with the bump-formed surface, and covers the surface of the bumps, in particular, the surface of a region near the bump-formed surface to embed bases of the bumps. In this state, the first protective membrane forming film is prevented from remaining on the upper portion of the bump. When the first protective membrane forming film is curable, the first protective membrane forming film in this state (the state in which the bases of the bumps are embedded) is then cured to finally form the first protective membrane, and when the first protective membrane forming film is non-curable, the first protective membrane forming film in this state (the state in which the bases of the bumps are embedded) and the state after this state functions as the first protective membrane. Then, as a matter of course, the adhesion of the first protective membrane is also prevented on the upper portions of the bumps. In particular, when the first protective membrane forming sheet of the present embodiment is used, the top portion of the bump protrudes from the first protective membrane forming film, and the remaining of the first protective membrane forming film and the adhesion of the first protective membrane are prevented on the upper portion of the bump even when the first protective membrane forming film in the first protective membrane forming sheet is attached to the bump-formed surface of the semiconductor wafer at a high speed. The reason of such excellent characteristics of the first protective membrane forming sheet of the present embodiment is that the first protective membrane forming sheet is formed by stacking the first base material, the buffer layer, the intermediate release layer, and the first protective membrane forming film in this order, and the intermediate release layer contains an ethylene-vinyl acetate copolymer.

Whether the first protective membrane forming film remains on the upper portion of the bump on the bump-formed surface and whether the first protective membrane adheres to the upper portion of the bump can be checked, for example, by acquiring imaging data of a scanning electron microscope (SEM) for the upper portion of the bump.

Regardless of whether the first protective membrane forming film is curable or non-curable, and when the first protective membrane forming film is curable, regardless of whether the first protective membrane forming film is thermosetting or energy ray-curable, the first protective membrane forming film may be formed of one layer (single layer) or may be formed of a plurality of layers of two or more layers. When the first protective membrane forming film is formed of a plurality of layers, the plurality of layers may be the same or different from each other, and a combination of the plurality of layers is not particularly limited.

In the present specification, “the plurality of layers may be the same or different from each other” means that “all the layers may be the same, all the layers may be different, or only some layers may be the same”, and further, “the plurality of layers are different from each other” means that “all the layers are different from each other in terms of at least one of the constituent material or the thickness”, and this is not only the case of the first protective membrane forming film.

Regardless of whether the first protective membrane forming film is thermosetting or energy ray-curable, the thickness of the first protective membrane forming film is preferably from 1 to 200 μm, more preferably from 10 to 150 μm, and particularly preferably from 20 to 130 μm. When the thickness of the first protective membrane forming film is more than or equal to the lower limit value, the effect exhibited by the first protective membrane forming film is further enhanced. For example, when the protective membrane is formed using the first protective membrane forming film, a protective membrane having a higher protective ability can be formed. When the thickness of the first protective membrane forming film is less than or equal to the upper limit value, the first protective membrane is prevented from having an excessive thickness.

As will be described later, when the first protective membrane is formed not only on the bump-formed surface of the semiconductor chip but also on a side surface of the semiconductor chip, it is necessary to use a semiconductor wafer having a groove formed on the bump-formed surface thereof. When the first protective membrane is also formed on a side surface of the semiconductor chip like this, the thickness of the first protective membrane forming film is preferably from 2 to 200 μm, more preferably from 30 to 150 μm, and particularly preferably from 30 to 130 μm in that the groove can be sufficiently filled with the first protective membrane forming film in addition to the same reason as described above.

On the other hand, when the first protective membrane is formed on the bump-formed surface of the semiconductor chip but the protective membrane is not formed on a side surface of the semiconductor chip, a semiconductor wafer having no groove on the bump-formed surface may be used as the semiconductor wafer. In such a case, for the same reason as described above (the effect exhibited by the first protective membrane forming film is further enhanced; an excessive thickness of the first protective membrane is suppressed), the thickness of the first protective membrane forming film is preferably from 1 to 100 μm, more preferably from 20 to 75 μm, and particularly preferably from 35 to 55 μm.

In the present specification, the “thickness of the first protective membrane forming film” means the thickness of the entire first protective membrane forming film, and for example, the thickness of the first protective membrane forming film including a plurality of layers means the total thickness of all the layers constituting the first protective membrane forming film.

In the present specification, unless otherwise specified, “thickness” means an average value of thicknesses measured at five points randomly selected in an object, and can be acquired using a constant pressure thickness measuring instrument in accordance with JIS K7130. This is not limited to the case of the first protective membrane forming film.

### <<Composition for Forming First Protective Membrane>>

The first protective membrane forming film can be formed using a composition for forming the first protective membrane containing a constituent material thereof. For example, the first protective membrane forming film can be formed by coating the composition for forming the first protective membrane to the target surface and drying the composition as necessary. The ratio of the contents of the components that are not vaporized at normal temperature in the composition for forming the first protective membrane is usually the same as the ratio of the contents of the components in the first protective membrane forming film. In the present specification, “room temperature” refers to a temperature that does not cause cooling or heating, that is, a normal temperature, and is, for example, a temperature from 15 to 25° C.

A thermosetting first protective membrane forming film can be formed using a composition for forming the thermosetting first protective membrane, an energy ray-curable first protective membrane forming film can be formed using a composition for forming the energy ray-curable first protective membrane, and a non-curable first protective membrane forming film can be formed using a composition for forming the non-curable first protective membrane.

In the present specification, when the first protective membrane forming film has both thermosetting properties and energy ray curability properties, the first protective membrane forming film is treated as being thermosetting when the contribution of thermal curing of the first protective membrane forming film is larger than the contribution of energy ray curing at the time of forming the first protective membrane. On the contrary, when the contribution of energy ray curing of the first protective membrane forming film is larger than the contribution of thermal curing at the time of forming the first protective membrane, the first protective membrane forming film is treated as energy ray-curable.

In the first protective membrane forming film, the proportion of the total content of one or two or more components to be described later in the first protective membrane forming film to the total mass of the first protective membrane forming film does not exceed 100 mass %.

Also in the composition for forming the first protective membrane, the proportion of the total content of one or two or more components to be described later in the composition for forming the first protective membrane to the total mass of the composition for forming the first protective membrane does not exceed 100 mass %.

The composition for forming the first protective membrane may be coated by a well-known method including, for example, methods using various coaters such as an air knife coater, a blade coater, a bar coater, a gravure coater, a roll coater, a roll knife coater, a curtain coater, a die coater, a knife coater, a screen coater, a Mayer bar coater, and a kiss coater.

The drying condition of the composition for forming the first protective membrane is not particularly limited regardless of whether the first protective membrane forming film is curable or non-curable, and when the first protective membrane forming film is curable, regardless of whether the first protective membrane forming film is thermosetting or energy ray curable. However, when the composition for forming the first protective membrane contains a solvent to be described later, it is preferable to heat and dry the composition. Then, the composition for forming the first protective membrane containing a solvent is preferably heated and dried, for example, at a temperature from 70 to 130° C. for a time period from 10 seconds to 5 minutes. However, the composition for forming the thermosetting first protective membrane is preferably heated and dried so that the composition itself and the thermosetting first protective membrane forming from the composition are not thermally cured.

Hereinafter, the thermosetting first protective membrane forming film, the energy ray-curable first protective membrane forming film, and the non-curable first protective membrane forming film will be described in more detail.

### Thermosetting First Protective Membrane Forming Film

Examples of the thermosetting first protective membrane forming film include a film containing a polymer component (A), a thermosetting component (B), a curing accelerator (C), a filler (D), and an additive (I).

The curing condition when the thermosetting first protective membrane forming film is cured to form the first protective membrane is not particularly limited as long as the first protective membrane has a degree of curing to such an extent that the first protective membrane sufficiently exhibits its function, and may be appropriately selected according to the type and the like of the thermosetting first protective membrane forming film.

For example, the heating temperature during thermal curing of the thermosetting first protective membrane forming film is preferably from 100 to 200° C., and it may be, for example, either from 110 to 170° C. or from 120 to 150° C. The heating time during the thermal curing is preferably from 0.5 to 5 hours, and may be, for example, either from 0.5 to 4 hours or from 1 to 3 hours.

### <Composition for Forming Thermosetting First Protective Membrane>

Examples of the composition for forming the thermosetting first protective membrane include a composition for forming the thermosetting first protective membrane (III) (in the present specification, it may be simply referred to as a “composition (III)”) containing a polymer component (A), a thermosetting component (B), a curing accelerator (C), a filler (D), and an additive (I).

### [Polymer Component (A)]

The polymer component (A) is a polymer compound for imparting membrane formability or flexibility to the thermosetting first protective membrane forming film. In the present specification, a product of polycondensation reaction is also included in the polymer compound.

The composition (III) and the thermosetting first protective membrane forming film may contain only one type of polymer component (A) or two or more types of polymer component (A). When the composition (III) and the thermosetting first protective membrane forming film contain two or more types of polymer component (A), their combination and proportions can be feely selected.

Examples of the polymer component (A) include poly(vinyl acetal), acrylic resins, urethane resins, phenoxy resins, silicone resins, and saturated polyester resins.

Among them, the polymer component (A) is preferably polyvinyl acetal.

Examples of the poly(vinyl acetal) in the polymer component (A) include those commonly known.

Among them, the poly(vinyl acetal) is preferably, for example, poly(vinyl formal) or poly(vinyl butyral), and is more preferably poly(vinyl butyral).

Examples of the poly(vinyl butyral) include those having constitutional units represented by Formulae (i-1), (i-2), and (i-3) below.

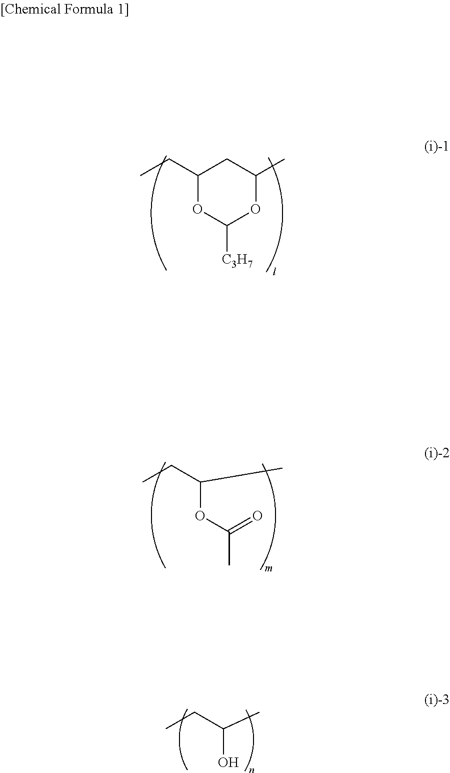

where l, m, and n are each independently an integer of 1 or more.

The weight average molecular weight (Mw) of the polyvinyl acetal is preferably from 5000 to 200000, and more preferably from 8000 to 100000. When the weight average molecular weight of the polyvinyl acetal is in such a range, the effect of preventing the thermosetting first protective membrane forming film from remaining on the upper portion of the bump when the thermosetting first protective membrane forming film is attached to the bump-formed surface is further enhanced.

In the present specification, unless otherwise noted, the “weight average molecular weight” is a polystyrene equivalent value measured by gel permeation chromatography (GPC).

A glass transition temperature (Tg) of the poly(vinyl acetal) is preferably from 40 to 80° C. and more preferably from 50 to 70° C. When the Tg of polyvinyl acetal is in such a range, the effect of preventing the thermosetting first protective membrane forming film from remaining on the upper portion of the bump is further enhanced when the thermosetting first protective membrane forming film is attached to the bump-formed surface.

The proportions of three or more types of monomers constituting the poly(vinyl acetal) can be optionally selected.

Examples of the acrylic resin in the polymer component (A) include known acrylic polymers.

The weight average molecular weight (Mw) of the acrylic resin is preferably from 5000 to 1000000, and more preferably from 8000 to 800000. When the weight average molecular weight of the acrylic resin is in such a range, the effect of preventing the thermosetting first protective membrane forming film from remaining on the upper portion of the bump when the thermosetting first protective membrane forming film is attached to the bump-formed surface is further enhanced.

The glass transition temperature (Tg) of the acrylic resin is preferably from −50 to 70° C. and more preferably from −30 to 60° C. When the Tg of the acrylic resin is in such a range, the effect of preventing the thermosetting first protective membrane forming film from remaining on the upper portion of the bump is further enhanced when the thermosetting first protective membrane forming film is attached to the bump-formed surface.

For the acrylic resin having two or more constitutional units, the glass transition temperature (Tg) of the acrylic resin can be calculated using Fox equation. For the Tg of the monomer deriving the constitutional unit used here, a value described in Polymer Data Handbook or Pressure Sensitive Adhesion Handbook can be used.

The acrylic resin may be constituted of only one type or two or more types of monomers. When two or more types of monomers constitute the acrylic resin, their combination and ratio can be freely selected.

Examples of the acrylic resin include polymers of one type or two or more types of (meth)acrylate; copolymers of two or more types of monomer selected from the group consisting of (meth)acrylic acid, itaconic acid, vinyl acetate, acrylonitrile, styrene, N-methylolacrylamide, and the like; and copolymers of one type or two or more types of (meth)acrylate and one type or two or more types of monomer selected from (meth)acrylic acid, itaconic acid, vinyl acetate, acrylonitrile, styrene, N-methylolacrylamide, and the like.

In the present specification, “(meth)acrylic acid” is a concept encompassing both “acrylic acid” and “methacrylic acid”. The same applies to terms similar to (meth)acrylic acid, and, for example, “(meth)acrylate” is a concept encompassing both “acrylate” and “methacrylate”, and a “(meth)acryloyl group” is a concept encompassing both an “acryloyl group” and a “methacryloyl group”.

Examples of the (meth)acrylate constituting the acrylic resin include:
an alkyl (meth)acrylate in which the alkyl group constituting the alkyl ester has a chain structure having from 1 to 18 carbons, such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, pentyl (meth)acrylate, hexyl (meth)acrylate, heptyl (meth)acrylate, 2-ethylhexyl (meth)acrylate, isooctyl (meth)acrylate, n-octyl (meth)acrylate, n-nonyl (meth)acrylate, isononyl (meth)acrylate, decyl (meth)acrylate, undecyl (meth)acrylate, dodecyl (meth)acrylate (lauryl (meth)acrylate), tridecyl (meth)acrylate, tetradecyl (meth)acrylate (myristyl (meth)acrylate), pentadecyl (meth)acrylate, hexadecyl (meth)acrylate (palmityl (meth)acrylate), heptadecyl (meth)acrylate, and octadecyl (meth)acrylate (stearyl (meth)acrylate);
a cycloalkyl (meth)acrylate, such as isobornyl (meth)acrylate and dicyclopentanyl (meth)acrylate;
an aralkyl (meth)acrylate, such as benzyl (meth)acrylate;
a cycloalkenyl (meth)acrylate, such as dicyclopentenyl (meth)acrylate;
a cycloalkenyloxyalkyl (meth)acrylate, such as dicyclopentenyloxyethyl (meth)acrylate;
(meth)acrylic acid imide;
a glycidyl group-containing (meth)acrylate, such as glycidyl (meth)acrylate;
a hydroxyl group-containing (meth)acrylate, such as hydroxymethyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate; and
a substituted amino group-containing (meth)acrylate, such as N-methylaminoethyl (meth)acrylate. Here, the “substituted amino group” means a group having a structure in which one or two hydrogen atoms of an amino group are substituted with a group other than hydrogen atoms.

The acrylic resin may have a functional group, such as a vinyl group, a (meth)acryloyl group, an amino group, a hydroxyl group, a carboxy group, or an isocyanate group, that can be attached to another compound. The functional group of the acrylic resin may be attached to another compound via a cross-linking agent (F) described later or may be directly attached to another compound without the cross-linking agent (F). When the acrylic resin is bonded to another compound by the functional group, for example, the reliability of the package produced using the thermosetting first protective membrane forming film tends to improve.

In the composition (III), the proportion of the content of the polymer component (A) to the total content of all the components other than the solvent is preferably from 5 to 25 mass % and more preferably from 5 to 15 mass % regardless of the type of the polymer component (A).

This is synonymous with that the proportion of the content of the polymer component (A) to the total mass of the thermosetting first protective membrane forming film in the thermosetting first protective membrane forming film is preferably from 5 to 25 mass % and more preferably from 5 to 15 mass % regardless of the type of the polymer component (A).

This is based on the fact that in the process of removing the solvent from the resin composition containing the solvent to form a resin membrane, the amount of components other than the solvent usually does not change, and the resin composition and the resin membrane have the same content ratio of components other than the solvent. Thus, in the present specification, for the content of components other than the solvent, only the content of the resin membrane with the solvent removed from the resin composition will be described below. This is not limited to the case of the thermosetting first protective membrane forming film.

The polymer component (A) may also correspond to the thermosetting component (B). In the present embodiment, when the composition (III) contains components corresponding to both the polymer component (A) and the thermosetting component (B), the composition (III) is regarded as containing the polymer component (A) and the thermosetting component (B).

### [Thermosetting Component (B)]

The thermosetting component (B) has thermosetting properties and is a component for thermally curing the thermosetting first protective membrane forming film.

The composition (III) and the thermosetting first protective membrane forming film may contain only one thermosetting component (B) or two or more thermosetting components (B). When two or more thermosetting components (B) are contained, their combination and proportions can be freely selected.

Examples of the thermosetting component (B) include an epoxy-based thermosetting resin, a thermosetting polyimide resin, and an unsaturated polyester resin, and an epoxy-based thermosetting resin is preferable.

In the present specification, the thermosetting polyimide resin is a generic term for a polyimide precursor and a thermosetting polyimide that form a polyimide resin by thermal curing.

### (Epoxy-Based Thermosetting Resin)

The epoxy-based thermosetting resin contains an epoxy resin (B1) and a thermal curing agent (B2).

The composition (III) and the thermosetting first protective membrane forming film may contain only one type of epoxy thermosetting resin or two or more types of epoxy thermosetting resin. When two or more types of epoxy thermosetting resin are contained, their combination and proportions can be freely selected.

### Epoxy Resin (B1)

Examples of the epoxy resin (B1) include known epoxy resins, for example, including a multifunctional epoxy resin, a biphenyl compound, a bisphenol A diglycidyl ether and a hydrogenated product thereof, an ortho-cresol novolak epoxy resin, a dicyclopentadiene-type epoxy resin, a biphenyl-type epoxy resin, a bisphenol A-type epoxy resin, a bisphenol F-type epoxy resin, a phenylene backbone-type epoxy resin, and a bifunctional or higher functional epoxy compound.

The epoxy resin (B1) may be an epoxy resin having an unsaturated hydrocarbon group. The epoxy resin having an unsaturated hydrocarbon group has higher compatibility with the acrylic resin than an epoxy resin having no unsaturated hydrocarbon group. Thus, the epoxy resin having an unsaturated hydrocarbon group tends to improve, for example, the reliability of the package produced using the thermosetting first protective membrane forming film.

Examples of the epoxy resin having an unsaturated hydrocarbon group include a compound having a structure in which a part of the epoxy group of the polyfunctional epoxy resin is converted into a group having an unsaturated hydrocarbon group. Such a compound is formed, for example, by addition reaction of (meth)acrylic acid or its derivative to an epoxy group.

Examples of the epoxy resin having an unsaturated hydrocarbon group include a compound having a structure in which a group having an unsaturated hydrocarbon group is directly bonded to an aromatic ring or the like constituting the epoxy resin.

The unsaturated hydrocarbon group is an unsaturated group with polymerizability, and specific examples include an ethenyl group (vinyl group), a 2-propenyl group (allyl group), a (meth)acryloyl group, and a (meth)acrylamide group, and an acryloyl group is preferred.

The number average molecular weight of the epoxy resin (B1) is not particularly limited, but is preferably from 300 to 30000, more preferably from 400 to 10000, and particularly preferably from 500 to 3000 from the viewpoint of the curability of the thermosetting first protective membrane forming film, and the strength and heat resistance of the cured product (for example, the first protective membrane) of the thermosetting first protective membrane forming film.

The epoxy equivalent weight of the epoxy resin (B1) is preferably from 100 to 1000 g/eq, and more preferably from 200 to 800 g/eq.

One type of the epoxy resin (B1) may be used alone or two or more types of the epoxy resin (B1) may be used in combination. When two or more types of the epoxy resin (B1) are used in combination, their combination and proportions can be freely selected.

### Thermal Curing Agent (B2)

The thermal curing agent (B2) functions as a curing agent for the epoxy resin (B1).

Examples of the thermal curing agent (B2) include a compound having, per molecule, two or more functional groups that can react with an epoxy group. Examples of the functional group include a phenolic hydroxyl group, an alcoholic hydroxyl group, an amino group, a carboxy group, and an anhydride group with an acid group dehydrated, and the functional group is preferably a phenolic hydroxyl group, an amino group, or an anhydride group with an acid group dehydrated, and more preferably a phenolic hydroxyl group or an amino group.

Among the thermal curing agents (B2), examples of the phenol-based curing agent having a phenolic hydroxyl group include a multifunctional phenolic resin, a biphenol, novolak-type phenolic resin, a dicyclopentadiene-type phenolic resin, and an aralkyl phenolic-type resin.

Among the thermal curing agents (B2), examples of the amine-based curing agent having an amino group include dicyandiamide (which may be hereinafter abbreviated as “DICY”).

The thermal curing agent (B2) may have an unsaturated hydrocarbon group.

Examples of the thermal curing agent (B2) having an unsaturated hydrocarbon group include a compound having a structure in which one or some hydroxyl groups of a phenolic resin are replaced by a group(s) having an unsaturated hydrocarbon group, and a compound having a structure in which a group having an unsaturated hydrocarbon group is directly attached to an aromatic ring of a phenolic resin.

The unsaturated hydrocarbon group in the thermal curing agent (B2) is the same as the unsaturated hydrocarbon group in the epoxy resin having an unsaturated hydrocarbon group described above.

The number average molecular weight of a resin component, such as, for example, a multifunctional phenolic resin, a novolak-type phenolic resin, a dicyclopentadiene-type phenolic resin, and an aralkyl-type phenolic resin, among the thermal curing agents (B2) is preferably from 300 to 30000, more preferably from 400 to 10000, and particularly preferably from 500 to 3000.

The molecular weight of the non-resin component, for example, bisphenol or dicyandiamide, among the thermal curing agents (B2) is not particularly limited, but is, for example, preferably from 60 to 500.

One type of the thermal curing agent (B2) may be used alone or two or more types of the thermal curing agent (B2) may be used in combination. When two or more types of the thermal curing agent (B2) are used in combination, their combination and ratios can be freely selected.

The content of the thermal curing agent (B2) in the thermosetting first protective membrane forming film is preferably from 0.1 to 500 parts by mass, more preferably from 1 to 200 parts by mass, and may be, for example, from 5 to 150 parts by mass, from 10 to 100 parts by mass, or from 15 to 75 parts by mass, with respect to 100 parts by mass of the content of the epoxy resin (B1). When the content of the thermal curing agent (B2) is more than or equal to the lower limit value, curing of the thermosetting first protective membrane forming film more easily proceeds. When the content of the thermal curing agent (B2) is less than or equal to the above upper limit value, the moisture absorption rate of the thermosetting first protective membrane forming film is reduced, and for example, the reliability of a package produced using the thermosetting first protective membrane forming film further improves.

The content of the thermosetting component (B) in the thermosetting first protective membrane forming film (for example, the total content of the epoxy resin (B1) and the thermal curing agent (B2)) is preferably from 600 to 1000 parts by mass with respect to 100 parts by mass of the content of the polymer component (A). When the content of the thermosetting component (B) is in such a range, the effect of preventing the thermosetting first protective membrane forming film from remaining at the upper portion of the bump when the thermosetting first protective membrane forming film is attached to the bump-formed surface is further enhanced, and a hard first protective membrane can be formed.

Furthermore, from the viewpoint of achieving such an effect more remarkably, the content of the thermosetting component (B) may be appropriately adjusted according to the type of polymer component (A).

For example, when the polymer component (A) is the polyvinyl acetal, the content of the thermosetting component (B) in the thermosetting first protective membrane forming film is preferably from 600 to 1000 parts by mass, more preferably from 600 to 900 parts by mass, and still more preferably from 600 to 800 parts by mass, with respect to 100 parts by mass of the content of the polymer component (A).

### [Curing Accelerator (C)]

The curing accelerator (C) is a component for adjusting the curing rate of the composition (III).

Examples of preferred curing accelerators (C) include a tertiary amine, such as triethylenediamine, benzyldimethylamine, triethanolamine, dimethylaminoethanol, and tris(dimethylaminomethyl)phenol; an imidazole (an imidazole in which one or more hydrogen atoms are replaced by groups other than hydrogen atoms), such as 2-methylimidazole, 2-phenylimidazole, 2-phenyl-4-methylimidazole, 2-phenyl-4,5-dihydroxymethylimidazole, and 2-phenyl-4-methyl-5-hydroxymethylimidazole; an organic phosphine (a phosphine in which one or more hydrogen atoms are replaced by organic groups), such as tributylphosphine, diphenylphosphine, and triphenylphosphine; and a tetraphenylboron salt, such as tetraphenylphosphonium tetraphenylborate and triphenylphosphine tetraphenylborate.

The composition (III) and the thermosetting first protective membrane forming film may contain only one type of the curing accelerator (C) or two or more types of the curing accelerator (C). When the composition and the thermosetting first protective membrane forming film contain two or more types of the curing accelerator (C), their combination and proportions can be feely selected.

The content of the curing accelerator (C) in the thermosetting first protective membrane forming film is preferably from 0.01 to 10 parts by mass, and more preferably from 0.1 to 5 parts by mass, with respect to 100 parts by mass of the content of the thermosetting component (B). The curing accelerator (C) is contained in an amount not lower than the lower limit described above, and this produces the effect of using the curing accelerator (C) more remarkably. When the content of the curing accelerator (C) is less than or equal to the above-described upper limit value, for example, the effect of preventing the movement of the highly polar curing accelerator (C) to the adhesion interface side with the adherend in the thermosetting first protective membrane forming film under high temperature and high humidity conditions and the segregation is enhanced, and for example, the reliability of the package produced using the thermosetting first protective membrane forming film further improves.

### [Filler (D)]

Adjusting the amount of the filler (D) in the composition (III) and the thermosetting first protective membrane forming film makes it possible to adjust the effect of preventing the thermosetting first protective membrane forming film from remaining at the upper portion the bump when the thermosetting first protective membrane forming film is attached to the bump-formed surface. In addition, the thermal expansion coefficient of the cured product (for example, the first protective membrane) of the thermosetting first protective membrane forming film can be more easily adjusted, and for example, by optimizing the thermal expansion coefficient of the first protective membrane with respect to the object on which the first protective membrane is to be formed, the reliability of the package produced using the thermosetting first protective membrane forming film further improves. In addition, as described later, to form the first protective membrane not only on the bump-formed surface of the semiconductor chip but also on a side surface of the semiconductor chip, the degree of filling can be adjusted when the first protective membrane forming film is filled in a groove provided on the bump-formed surface of the semiconductor wafer. In addition, using the thermosetting first protective membrane forming film containing the filler (D) makes it possible to reduce the moisture absorption rate of the cured product (for example, the first protective membrane) of the thermosetting first protective membrane forming film and improve the heat dissipation property.

The filler (D) may be either an organic filler or an inorganic filler, but is preferably an inorganic filler.

Examples of a preferred inorganic filler include powders, such as those of silica, alumina, talc, calcium carbonate, titanium white, red iron oxide, silicon carbide, or boron nitride; spheronized beads of these inorganic fillers; surface-modified products of these inorganic fillers; single crystal fibers of these inorganic fillers; and glass fibers.

Among these, the inorganic filler is preferably silica or alumina.

The composition (III) and the thermosetting first protective membrane forming film may contain only one type of the filler (D) or two or more types of the filler (D). When the composition (III) and the thermosetting first protective membrane forming film contain two or more types of the filler (D), their combination and proportions can be feely selected.

The proportion of the content of the filler (D) to the total mass of the thermosetting first protective membrane forming film in the thermosetting first protective membrane forming film is preferably from 5 to 45 mass %, more preferably from 5 to 40 mass %, and still more preferably from 5 to 30 mass %. When the proportion is in such a range, the effect of preventing the thermosetting first protective membrane forming film from remaining at the upper portion of the bump when the thermosetting first protective membrane forming film is attached to the bump-formed surface is further enhanced, and the thermal expansion coefficient can be more easily adjusted.

### [Additive (I)]

Adjusting the type or amount of the additive (I) in the composition (III) and the thermosetting first protective membrane forming film makes it possible to adjust the effect of preventing the thermosetting first protective membrane forming film from remaining at the upper portion of the bump when the thermosetting first protective membrane forming film is attached to the bump-formed surface.

In particular, examples of the additive (I) preferable in that the effect of preventing the remaining of the thermosetting first protective membrane forming film is further enhanced include a rheology control agent, a surfactant, and silicone oil.

More specifically, examples of the rheology control agent includes a polyhydroxy carboxylic acid ester, a polyvalent carboxylic acid, and a polyamide resin.

Examples of the surfactant include a modified siloxane and an acrylic polymer.

Examples of the silicone oil include an aralkyl-modified silicone oil and a modified polydimethylsiloxane, and examples of a modified group include an aralkyl group, a polar group such as a hydroxy group, and a group having an unsaturated bond such as a vinyl group and a phenyl group.

Examples of the additive (I) also include other various versatile additives, such as a plasticizer, an antistatic agent, an antioxidant, a gettering agent, an ultraviolet absorber, and a tackifier.

The composition (III) and the thermosetting first protective membrane forming film may contain only one type of the additive (I) or two or more types of the additive (I). When two or more types of the additive (I) are contained, their combination and proportions can be feely selected.

The contents of the additive (I) in the composition (III) and the thermosetting first protective membrane forming film are not particularly limited, and can be appropriately adjusted according to the type and purpose.

For example, when the purpose is to adjust the effect of preventing the remaining of the thermosetting first protective membrane forming film described above, the proportion of the content of the additive (I) to the total mass of the thermosetting first protective membrane forming film in the thermosetting first protective membrane forming film is preferably from 0.5 to 10 mass %, more preferably from 0.5 to 7 mass %, and still more preferably from 0.5 to 5 mass %.

### [Coupling Agent (E)]

The composition (III) and the thermosetting first protective membrane forming film may contain a coupling agent (E). When used as the coupling agent (E), one having a functional group capable of reacting with an inorganic compound or an organic compound makes it possible to improve adhesiveness and close contact of the thermosetting first protective membrane forming film to an adherend. The coupling agent (E) improves the water resistance of the cured product (for example, the first protective membrane) of the thermosetting first protective membrane forming film without impairing the heat resistance.

The coupling agent (E) is preferably a compound having a functional group that can react with a functional group contained in the polymer component (A), the thermosetting component (B), or the like and more preferably a silane coupling agent. Preferred examples of the silane coupling agent include 3-glycidyloxypropyltrimethoxysilane, 3-glycidyloxypropylmethyldiethoxysilane, 3-glycidyloxypropyltriethoxysilane, 3-glycidyloxymethyldiethoxysilane, 2-(3,4-epoxycyclohexyl)ethyltrimethoxysilane, 3-methacryloyloxypropyltrimethoxysilane, 3-aminopropyltrimethoxysilane, 3-(2-aminoethylamino)propyltrimethoxysilane, 3-(2-aminoethylamino)propylmethyldiethoxysilane, 3-(phenylamino)propyltrimethoxysilane, 3-anilinopropyltrimethoxysilane, 3-ureidopropyltriethoxysilane, 3-mercaptopropyltrimethoxysilane, 3-mercaptopropylmethyldimethoxysilane, bis(3-triethoxysilylpropyl)tetrasulfane, methyltrimethoxysilane, methyltriethoxysilane, vinyltrimethoxysilane, vinyltriacetoxysilane, and imidazole silane.

The composition (III) and the thermosetting first protective membrane forming film may contain only one type of the coupling agent (E) or two or more types of the coupling agent (E). When two or more types of the coupling agent (E) are contained, their combination and proportions can be freely selected.

When the coupling agent (E) is used, the content of the coupling agent (E) in the thermosetting first protective membrane forming film may be, for example, from 0.03 to 20 parts by mass with respect to 100 parts by mass of the total content of the polymer component (A) and the thermosetting component (B). When the content of the coupling agent (E) is more than or equal to the lower limit value, effects due to the use of the coupling agent (E), such as improvement in dispersibility of the filler (D) in a resin and improvement in adhesiveness of the thermosetting first protective membrane forming film to an adherend, are more remarkably provided. When the content of the coupling agent (E) is less than or equal to the upper limit described above, this further prevents the generation of outgas.

### [Cross-Linking Agent (F)]

When a component having a functional group such as a vinyl group, a (meth)acryloyl group, an amino group, a hydroxyl group, a carboxy group, or an isocyanate group bondable to another compound is used as the polymer component (A), the composition (III) and the thermosetting first protective membrane forming film may contain a cross-linking agent (F). The cross-linking agent (F) is a component for cross-linking by bonding the functional group in the polymer component (A) to another compound, and by cross-linking in this way, the initial adhesive strength and cohesive strength of the thermosetting first protective membrane forming film can be adjusted.

Examples of the cross-linking agent (F) include an organic polyvalent isocyanate compound, an organic polyvalent imine compound, a metal chelate-based cross-linking agent (a cross-linking agent having a metal chelate structure), and an aziridine-based cross-linking agent (a cross-linking agent having an aziridinyl group).

Examples of the organic polyvalent isocyanate compound include an aromatic polyvalent isocyanate compound, an aliphatic polyvalent isocyanate compound, and an alicyclic polyvalent isocyanate compound (hereinafter, these compounds may be abbreviated collectively as “the aromatic polyvalent isocyanate compound or the like”); a trimer, an isocyanurate, and an adducts of the aromatic polyvalent isocyanate compound or the like; and a terminal isocyanate urethane prepolymer which is a reactant of the aromatic polyvalent isocyanate compound or the like and a polyol compound. The “adduct” means a reaction product of the aromatic polyvalent isocyanate compound, aliphatic polyvalent isocyanate compound, or alicyclic isocyanate compound with a low-molecular active hydrogen-containing compound, such as ethylene glycol, propylene glycol, neopentyl glycol, trimethylolpropane, or castor oil. Examples of the adduct include a xylylene diisocyanate adduct of trimethylolpropane as described later. In the present specification, “terminal isocyanate urethane prepolymer” means a prepolymer having a urethane bond and having an isocyanate group at the terminal part of the molecule.

Examples of the organic polyvalent isocyanate compound more specifically include 2,4-tolylene diisocyanate; 2,6-tolylene diisocyanate; 1,3-xylylene diisocyanate; 1,4-xylene diisocyanate; diphenylmethane-4,4′-diisocyanate; diphenylmethane-2,4′-diisocyanate; 3-methyldiphenylmethane diisocyanate; hexamethylene diisocyanate; isophorone diisocyanate; dicyclohexylmethane-4,4′-diisocyanate; dicyclohexylmethane-2,4′-diisocyanate; compounds in which any one, two or more of tolylene diisocyanate, hexamethylene diisocyanate, and xylylene diisocyanate are added to one, some, or all of the hydroxyl groups of a polyol, such as trimethylolpropane; and lysine diisocyanate.

Examples of the organic polyvalent imine compound include N,N′-diphenylmethane-4,4′-bis(1-aziridinecarboxyamide), trimethylolpropane-tri-β-aziridinyl propionate, tetramethylolmethane-tri-β-aziridinyl propionate, and N,N′-toluene-2,4-bis(1-aziridinecarboxyamide)triethylenemelamine.

When the organic polyvalent isocyanate compound is used as the cross-linking agent (F), a hydroxyl group-containing polymer is preferably used as the polymer component (A). When the cross-linking agent (F) has an isocyanate group and the polymer component (A) has a hydroxyl group, a cross-linked structure can be easily introduced into the thermosetting first protective membrane forming film by the reaction between the cross-linking agent (F) and the polymer component (A).

The composition (III) and the thermosetting first protective membrane forming film may contain only one type of the cross-linking agent (F) or two or more types of the cross-linking agent (F). When two or more types of the cross-linking agent (F) are contained, their combination and proportions can be freely selected.

When the cross-linking agent (F) is used, the content of the cross-linking agent (F) in the composition (III) may be, for example, from 0.01 to 20 parts by mass with respect to 100 parts by mass of the content of the polymer component (A). When the content of the cross-linking agent (F) is more than or equal to the lower limit described above, this produces the effect of using the cross-linking agent (F) more remarkably. When the content of the cross-linking agent (F) is less than or equal to the upper limit described above, and this prevents overuse of the cross-linking agent (F).

### [Additional Component]

The composition (III) and the thermosetting first protective membrane forming film may contain additional components that do not correspond to any of the polymer component (A), the thermosetting component (B), the curing accelerator (C), the filler (D), the additive (I), the coupling agent (E), and the cross-linking agent (F) as long as the effects of the present invention are not impaired.

Examples of the additional component include an energy ray-curable resin and a photopolymerization initiator.

The composition (III) and the thermosetting first protective membrane forming film may contain only one type of the additional component or two or more types of the additional component. When two or more types of the additional component are contained, their combination and proportions can be freely selected.

The contents of the additional components in the composition (III) and the thermosetting first protective membrane forming film are not particularly limited, and may be appropriately selected according to the purpose.

### [Solvent]

The composition (III) preferably further contains a solvent. The composition containing a solvent (III) has good handleability.

The solvent is not particularly limited, but preferred examples include a hydrocarbon, such as toluene and xylene; an alcohol, such as methanol, ethanol, 2-propanol, isobutyl alcohol (2-methylpropan-1-ol), and 1-butanol; an ester, such as ethyl acetate; a ketone, such as acetone and methyl ethyl ketone; an ether, such as tetrahydrofuran; and an amide, such as dimethylformamide and N-methylpyrrolidone (a compound having an amide bond).

The composition (III) may contain only one type of the solvent or two or more types of the solvent, and when two or more types of the solvent are contained, their combination and proportions can be freely selected.

More preferable examples of the solvent contained in the composition (III) include methyl ethyl ketone from the viewpoint that the components contained in the composition (III) can be more uniformly mixed.

The content of the solvent of the composition (III) is not particularly limited, and for example, it may be appropriately selected according to the types of components other than the solvent.

From the viewpoint that an intended effect of the present invention (high-speed attachment of the first protective membrane forming sheet and penetrability of the first protective membrane forming film to be described later) is further enhanced, a preferable example of the thermosetting first protective membrane forming film includes a thermosetting first protective membrane forming film containing the polymer component (A), the thermosetting component (B), the curing accelerator (C), the filler (D), and the additive (I), in which the proportion of a total content of the polymer component (A), the thermosetting component (B), the curing accelerator (C), the filler (D), and the additive (I) to the total mass of the thermosetting first protective membrane forming film in the thermosetting first protective membrane forming film is 85 mass % or more, preferably 90 mass % or more, more preferably 95 mass % or more.

In view of the above, a more preferable example of the thermosetting first protective membrane forming film includes the polymer component (A), the thermosetting component (B), the curing accelerator (C), the filler (D), and the additive (I), in which the polymer component (A) is polyvinyl acetal, the thermosetting component (B) is the epoxy resin (B1) and the thermal curing agent (B2), the additive (I) is one or two or more selected from the group consisting of a rheology control agent, a surfactant, and a silicone oil, and the proportion of the total content of the polymer component (A), the thermosetting component (B), the curing accelerator (C), the filler (D), and the additive (I) with respect to the total mass of the thermosetting first protective membrane forming film in the thermosetting first protective membrane forming film is 85 mass % or more, preferably 90 mass % or more, and more preferably 95 mass % or more.

The thickness of the thermosetting first protective membrane forming film is preferably from 2 to 7 times, more preferably from 3 to 6 times the thickness of the intermediate release layer.

### <Method for Manufacturing Composition for Forming Thermosetting First Protective Membrane>

The composition for forming the thermosetting first protective membrane such as the composition (III) is produced by blending each component for constituting the composition.

The order of adding the components during blending is not particularly limited, and two or more components may be added simultaneously.

The method of mixing the components during blending is not particularly limited and is appropriately selected from known methods, such as a method of mixing by rotating a stirring bar or a stirring blade; a method of mixing using a mixer; and a method of mixing by applying an ultrasonic wave.

The temperature and time when the components are added and mixed are not particularly limited as long as each of the blended components is not degraded, and are appropriately controlled. The temperature is preferably from 15 to 30° C.

### Energy Ray-Curable First Protective Membrane Forming Film

Examples of the energy ray-curable first protective membrane forming film include a film containing the energy ray-curable component (a), a filler, and an additive.

The curing condition when the energy ray-curable first protective membrane forming film is cured to form the first protective membrane is not particularly limited as long as the first protective membrane has a degree of curing to such an extent that the first protective membrane sufficiently exhibits its function, and may be appropriately selected according to the type and the like of the energy ray-curable first protective membrane forming film.

For example, the illuminance of the energy ray during curing of the energy ray-curable first protective membrane forming film is preferably from 180 to 280 mW/cm². In addition, the dose of the energy rays during the curing is preferably from 450 to 1000 mJ/cm².

### <Composition for Forming Energy Ray-Curable First Protective Membrane>

Examples of the composition for the energy ray-curable first protective membrane include a composition for forming the energy ray-curable first protective membrane (IV) (in the present specification, may be simply referred to as “composition (IV)”) containing an energy ray-curable component (a), a filler, and an additive.

[Energy Ray-Curable Component (a)]

The energy ray-curable component (a) is a component that is cured by irradiation with an energy ray, and is also a component for imparting membrane forming properties, flexibility, and the like to the energy ray-curable first protective membrane forming film.

The energy ray-curable component (a) is preferably uncured, preferably has pressure sensitive adhesion, and more preferably is uncured and has pressure sensitive adhesion.

Examples of the energy ray-curable component (a) include a polymer (a1) having an energy ray-curable group and having a weight average molecular weight from 80000 to 2000000 and a compound (a2) having an energy ray-curable group and having a molecular weight of from 100 to 80000. The polymer (a1) may be at least partially crosslinked with a cross-linking agent or may be uncrosslinked.

(Polymer (a1) Having an Energy Ray-Curable Group and Having a Weight Average Molecular Weight from 80000 to 2000000)

Examples of the polymer (a1) having an energy ray-curable group and having a weight average molecular weight from 80000 to from 2000000 include an acrylic resin (a1-1) having a structure in which an acrylic polymer (a11) having a functional group capable of reacting with a group of another compound and an energy ray-curable compound (a12) having a group reactive with the functional group and an energy ray-curable group such as an energy ray-curable double bond are polymerized.

Examples of the functional group capable of reacting with a group of another compound include a hydroxyl group, a carboxy group, an amino group, a substituted amino group (a group having a structure in which one or two hydrogen atoms of an amino group are substituted with a group other than a hydrogen atom), and an epoxy group. However, in terms of preventing corrosion of a circuit of a semiconductor wafer, semiconductor chip, or the like, the functional group is preferably a group other than a carboxy group.

Among these, the functional group is preferably a hydroxyl group.

Acrylic Polymer (a11) Having Functional Group

Examples of the acrylic polymer (a11) having a functional group include those having a structure in which an acrylic monomer having the functional group and an acrylic monomer not having the functional group are copolymerized, and those having a structure in which a monomer (non-acrylic monomer) other than the acrylic monomer is further copolymerized in addition to these monomers may be used.

In addition, the acrylic polymer (a11) may be a random copolymer or a block copolymer.

Examples of the acrylic monomer having a functional group include a hydroxyl group-containing monomer, a carboxy group-containing monomer, an amino group-containing monomer, a substituted amino group-containing monomer, and an epoxy group-containing monomer.

Examples of the hydroxyl group-containing monomer include a hydroxyalkyl (meth)acrylate, such as hydroxymethyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate; and a non-(meth)acrylic unsaturated alcohol (an unsaturated alcohol having no (meth)acryloyl backbone), such as vinyl alcohol and allyl alcohol.

Examples of the carboxy group-containing monomer include an ethylenically unsaturated monocarboxylic acid (a monocarboxylic acid having an ethylenically unsaturated bond), such as (meth)acrylic acid and crotonic acid; an ethylenically unsaturated dicarboxylic acid (a dicarboxylic acid having an ethylenically unsaturated bond), such as fumaric acid, itaconic acid, maleic acid, and citraconic acid; an anhydride of the ethylenically unsaturated dicarboxylic acid; and a carboxyalkyl (meth)acrylate, such as 2-carboxyethyl methacrylate.

The acrylic monomer having a functional group is preferably a hydroxyl group-containing monomer or a carboxy group-containing monomer and more preferably a hydroxyl group-containing monomer.

The acrylic polymer (a11) may be constituted of only one type or two or more types of the acrylic monomer having a functional group described above. When two or more types of the acrylic monomer having a functional group constitute the acrylic polymer (a11), their combination and proportions can be freely selected.

Examples of the acrylic monomer having no functional group include an alkyl (meth)acrylate in which the alkyl group constituting the alkyl ester has a chain structure having from 1 to 18 carbons, such as methyl (meth)acrylate, ethyl (meth)acrylate, n-propyl (meth)acrylate, isopropyl (meth)acrylate, n-butyl (meth)acrylate, isobutyl (meth)acrylate, sec-butyl (meth)acrylate, tert-butyl (meth)acrylate, pentyl (meth)acrylate, hexyl (meth)acrylate, heptyl (meth)acrylate, 2-ethylhexyl (meth)acrylate, isooctyl (meth)acrylate, n-octyl (meth)acrylate, n-nonyl (meth)acrylate, isononyl (meth)acrylate, decyl (meth)acrylate, undecyl (meth)acrylate, dodecyl (meth)acrylate (lauryl (meth)acrylate), tridecyl (meth)acrylate, tetradecyl (meth)acrylate (myristyl (meth)acrylate), pentadecyl (meth)acrylate, hexadecyl (meth)acrylate (palmityl (meth)acrylate), heptadecyl (meth)acrylate, and octadecyl (meth)acrylate (stearyl (meth)acrylate).

Examples of the acrylic monomer having no functional group also include an alkoxyalkyl group-containing (meth)acrylate, such as methoxymethyl (meth)acrylate, methoxyethyl (meth)acrylate, ethoxymethyl (meth)acrylate, and ethoxyethyl (meth)acrylate; a (meth)acrylate having an aromatic group, including an aryl (meth)acrylate, such as phenyl (meth)acrylate; a non-crosslinkable (meth)acrylamide and a derivative thereof; and a (meth)acrylate having a non-crosslinkable tertiary amino group, such as N,N-dimethylaminoethyl (meth)acrylate and N,N-dimethylaminopropyl (meth)acrylate.

The acrylic polymer (a11) may be constituted of only one type or two or more types of the acrylic monomer having no functional group described above. When two or more types of the acrylic monomer having no functional group constitute the acrylic polymer (a11), their combination and proportions can be freely selected.

Examples of the non-acrylic monomer include an olefin, such as ethylene and norbornene; vinyl acetate; and styrene.

The acrylic polymer (a11) may be constituted of only one type or two or more types of the non-acrylic monomer described above. When two or more types of the non-acrylic monomer constitute the acrylic polymer (a11), their combination and proportions can be freely selected.

In the acrylic polymer (a11), the proportion of the amount (content) of the constitutional unit derived from the acrylic monomer having a functional group to the total amount of the constitutional units constituting the acrylic polymer (a11) is preferably from 0.1 to 50 mass %, more preferably from 1 to 40 mass %, and even more preferably from 3 to 30 mass %. When the proportion is in such a range, in the acrylic resin (a1-1) produced through copolymerization of the acrylic polymer (a11) and the energy ray-curable compound (a12), the content of the energy ray-curable group can be easily adjusted so that the degree of curing of the cured product (for example, the first protective membrane) of the energy ray-curable first protective membrane forming film falls within a preferable range.

The acrylic resin (a1-1) may be constituted of only one type or two or more types of the acrylic polymer (a11) described above. When two or more types of the acrylic polymer (a11) constitute the acrylic resin (a1-1), their combination and proportions can be freely selected.

In the energy ray-curable first protective membrane forming film, the proportion of the content of the acrylic resin (a1-1) to the total mass of the energy ray-curable first protective membrane forming film is preferably from 1 to 40 mass %, more preferably from 2 to 30 mass %, and particularly preferably from 3 to 20 mass %.

Energy Ray-Curable Compound (a12)

The energy ray-curable compound (a12) is preferably a compound having one type or two or more types of groups selected from the group consisting of an isocyanate group, an epoxy group, and a carboxy group, as a group that can react with a functional group contained in the acrylic polymer (a11); and more preferably a compound having an isocyanate group as the group described above. When the energy ray-curable compound (a12) has, for example, an isocyanate group as the group described above, this isocyanate group readily reacts with a hydroxyl group of the acrylic polymer (a11) having this hydroxyl group as the functional group described above.

The energy ray-curable compound (a12) has preferably from 1 to 5 and more preferably 1 or 2 energy ray-curable groups per molecule.

Examples of the energy ray-curable compound (a12) include 2-methacryloyloxyethyl isocyanate, meta-isopropenyl-α,α-dimethylbenzyl isocyanate, methacryloyl isocyanate, allyl isocyanate, and 1,1-(bisacryloyloxymethyl)ethyl isocyanate; acryloyl monoisocyanate compounds formed by a reaction of a diisocyanate compound or a polyisocyanate compound with hydroxyethyl (meth)acrylate; and an acryloyl monoisocyanate compound formed by a reaction of a diisocyanate compound or a polyisocyanate compound with a polyol compound, and hydroxyethyl (meth)acrylate.

Among these, the energy ray-curable compound (a12) is preferably 2-methacryloyloxyethyl isocyanate.

The acrylic resin (a1-1) may be constituted of only one type or two or more types of the energy ray-curable compound (a12) described above. When two or more types of the energy ray-curable compound (a12) constitute the acrylic resin (a1-1), their combination and proportions can be freely selected.

In the acrylic resin (a1-1), the proportion of the content of the energy ray-curable group derived from the energy ray-curable compound (a12) to the content of the functional group derived from the acrylic polymer (a1 l) is preferably from 20 to 120 mol %, more preferably from 35 to 100 mol %, and even more preferably from 50 to 100 mol %. When the proportion of the content is in such a range, the adhesive strength of the cured product (for example, the first protective membrane) of the energy ray-curable first protective membrane forming film further increases. When the energy ray-curable compound (a12) is a monofunctional compound (having one group described above per molecule), the upper limit of the proportion of the content is 100 mol %, but when the energy ray-curable compound (a12) is a multifunctional compound (having two or more groups described above per molecule), the upper limit of the proportion of the content may exceed 100 mol %.

The weight average molecular weight (Mw) of the polymer (a1) is preferably from 100000 to 2000000, and more preferably from 300000 to 1500000.

When the polymer (a1) is at least partially crosslinked with a cross-linking agent, the polymer (a1) may be a polymer in which a monomer not corresponding to any of the monomers described above as those constituting the acrylic polymer (a11) and having a group reacting with the cross-linking agent is polymerized and crosslinked at the group reacting with the cross-linking agent, or may be a polymer in which the monomer is crosslinked at the group derived from the energy ray-curable compound (a12) and reacting with the functional group described above.

The composition (IV) and the energy ray-curable first protective membrane forming film may contain only one type of the polymer (a1) or two or more types of the polymer (a1), and two or more types of the polymer (a1) are contained, their combination and ratios can be freely selected.

(Compound (a2) Having Energy Ray-Curable Group and Having Molecular Weight from 100 to 80000)

Examples of the energy ray-curable group in the compound (a2) having an energy ray-curable group and having a molecular weight from 100 to 80000 include a group containing an energy ray-curable double bond, and preferred examples thereof include a (meth)acryloyl group and a vinyl group.

The compound (a2) is any compound satisfying the conditions described above and not particularly limited, and examples include a low-molecular weight compound having an energy ray-curable group, an epoxy resin having an energy ray-curable group, and a phenolic resin having an energy ray-curable group.

Among the compounds (a2), examples of the low-molecular weight compound having an energy ray-curable group include a multifunctional monomer or oligomer, and an acrylate-based compound having a (meth)acryloyl group is preferred.

Examples of the acrylate-based compound include a bifunctional (meth)acrylate, such as 2-hydoxy-3-(meth)acryloyloxypropyl methacrylate, polyethylene glycol di(meth)acrylate, propoxylated ethoxylated bisphenol A di(meth)acrylate, 2,2-bis[4-((meth)acryloxypolyethoxy)phenyl]propane, ethoxylated bisphenol A di(meth)acrylate, 2,2-bis[4-((meth)acryloxy diethoxy)phenyl]propane, 9,9-bis[4-(2-(meth)acryloyloxy ethoxy)phenyl]fluorene, 2,2-bis[4-((meth)acryloxy polypropoxy)phenyl]propane, tricyclodecane dimethanol di(meth)acrylate, 1,10-decanediol di(meth)acrylate, 1,6-hexanediol di(meth)acrylate, 1,9-nonanediol di(meth)acrylate, dipropylene glycol di(meth)acrylate, tripropylene glycol di(meth)acrylate, polypropylene glycol di(meth)acrylate, poly(tetramethylene glycol) di(meth)acrylate, ethylene glycol di(meth)acrylate, diethylene glycol di(meth)acrylate, triethylene glycol di(meth)acrylate, 2,2-bis[4-((meth)acryloxyethoxy)phenyl]propane, neopentyl glycol di(meth)acrylate, ethoxylated polypropylene glycol di(meth)acrylate, and 2-hydoxy-1,3-di(meth)acryloxypropane; a multifunctional (meth)acrylate, such as tris(2-(meth)acryloxyethyl)isocyanurate, s-caprolactone-modified tris-(2-(meth)acryloxyethyl)isocyanurate, ethoxylated glycerin tri(meth)acrylate, pentaerythritol tri(meth)acrylate, trimethylolpropane tri(meth)acrylate, ditrimethylolpropane tetra(meth)acrylate, ethoxylated pentaerythritol tetra(meth)acrylate, pentaerythritol tetra(meth)acrylate, dipentaerythritol poly(meth)acrylate, and dipentaerythritol hexa(meth)acrylate; and a multifunctional (meth)acrylate oligomer, such as a urethane (meth)acrylate oligomer.

Among the compounds (a2), for the epoxy resin having an energy ray-curable group and the phenolic resin having an energy ray-curable group, for example, those described in paragraph [0043] and the like in “JP 2013-194102 A” can be used. Such a resin also corresponds to a resin constituting a thermosetting component described later, but is handled as the compound (a2) in the present embodiment.

The weight average molecular weight of the compound (a2) is preferably from 100 to 30000, and more preferably from 300 to 10000.

The composition (IV) and the energy ray-curable first protective membrane forming film may contain only one type of the compound (a2) or two or more types of the compound (a2), and when two or more types of the compound (a2) are contained, their combination and proportions can be freely selected.

### [Polymer (b) Having No Energy Ray-Curable Group]

When the composition (IV) and the energy ray-curable first protective membrane forming film contain the compound (a2) as the energy ray-curable component (a), the composition (IV) and the energy ray-curable first protective membrane forming film preferably further contain a polymer (b) having no energy ray-curable group.

The polymer (b) may be at least partially crosslinked with a cross-linking agent or may be uncrosslinked.

Examples of the polymer (b) having no energy ray-curable group include an acrylic polymer, a phenoxy resin, a urethane resin, a polyester, a rubber-based resin, and an acrylic urethane resin.

Among these, the polymer (b) is preferably an acrylic polymer (which may be hereinafter abbreviated as the “acrylic polymer (b-1)”).

The acrylic polymer (b-1) is a known acrylic polymer and may be a homopolymer of one type of acrylic monomer, a copolymer of two or more types of acrylic monomers, and a copolymer of one type or two or more types of acrylic monomers and one type or two or more types of monomers (non-acrylic monomers) other than acrylic monomers.

Examples of the acrylic monomer constituting the acrylic polymer (b-1) include an alkyl (meth)acrylate, a (meth)acrylate having a cyclic backbone, a glycidyl group-containing (meth)acrylate, a hydroxyl group-containing (meth)acrylate, and a substituted amino group-containing (meth)acrylate. Here the “substituted amino group” is as described above.

Examples of the alkyl (meth)acrylate include the same as those for the acrylic monomer (such as an alkyl (meth)acrylate in which the alkyl group constituting the alkyl ester has a chain structure having from 1 to 18 carbons) having no functional group and constituting the acrylic polymer (a11) described above.

Examples of the (meth)acrylate having a cyclic backbone include a cycloalkyl (meth)acrylate, such as isobornyl (meth)acrylate and dicyclopentanyl (meth)acrylate; an aralkyl (meth)acrylate, such as benzyl (meth)acrylate; a cycloalkenyl (meth)acrylate, such as dicyclopentenyl (meth)acrylate; and a cycloalkenyloxyalkyl (meth)acrylate, such as dicyclopentenyloxyethyl (meth)acrylate.

Examples of the glycidyl group-containing (meth)acrylate include glycidyl (meth)acrylate.

Examples of the hydroxyl group-containing (meth)acrylate include hydroxymethyl (meth)acrylate, 2-hydroxyethyl (meth)acrylate, 2-hydroxypropyl (meth)acrylate, 3-hydroxypropyl (meth)acrylate, 2-hydroxybutyl (meth)acrylate, 3-hydroxybutyl (meth)acrylate, and 4-hydroxybutyl (meth)acrylate.

Examples of the substituted amino group-containing (meth)acrylate include N-methylaminoethyl(meth)acrylate.

Examples of the non-acrylic monomer constituting the acrylic polymer (b-1) include an olefin, such as ethylene and norbornene; vinyl acetate; and styrene.

Examples of the polymer (b) having no energy ray-curable group and at least partially crosslinked with a cross-linking agent include those in which a reactive functional group in the polymer (b) is reacted with the cross-linking agent.

The reactive functional group is appropriately selected according to the type of cross-linking agent or the like and is not particularly limited. For example, when the cross-linking agent is a polyisocyanate compound, examples of the reactive functional group include a hydroxyl group, a carboxy group, and an amino group, and among these, a hydroxyl group, which has high reactivity with an isocyanate group, is preferred. In addition, when the cross-linking agent is an epoxy-based compound, examples of the reactive functional group include a carboxy group, an amino group, and an amide group, and among these, a carboxy group, which has high reactivity with an epoxy group, is preferred. However, in terms of preventing corrosion of a circuit of a semiconductor wafer or semiconductor chip, the reactive functional group is preferably a group other than a carboxy group.

Examples of the polymer (b) having a reactive functional group and having no energy ray-curable group include those produced by polymerization of the monomer having at least a reactive functional group. In the case of the acrylic polymer (b-1), the monomer having a reactive functional group is used as one or both of the acrylic monomer and the non-acrylic monomer exemplified as the monomer constituting the acrylic polymer (b-1). Examples of the polymer (b) having a hydroxyl group as a reactive functional group include those produced, for example, by polymerization of a hydroxyl group-containing (meth)acrylate, and in addition to these, examples include those produced by polymerization of a monomer having a structure in which one or more hydrogen atoms are replaced by the reactive functional group(s) in the acrylic monomer or non-acrylic monomer exemplified above.

In the polymer (b) having a reactive functional group, the proportion of the amount (content) of the constitutional unit derived from the monomer having a reactive functional group to the total amount of the constitutional units constituting this polymer (b) is preferably from 1 to 20 mass % and more preferably from 2 to 10 mass %. The constitutional unit is contained in the proportion in such a range, and this allows the degree of crosslinking to be in a more preferred range in the polymer (b).

The weight average molecular weight (Mw) of the polymer (b) having no energy ray-curable group is preferably from 10000 to 2000000 and more preferably from 100000 to 1500000 from the viewpoint of allowing a composition (IV) to have better membrane formability.

The composition (IV) and the energy ray-curable first protective membrane forming film may contain only one type of the polymer (b) having no energy ray-curable group or two or more types of the polymer (b), and when two or more types of the polymer (b) are contained, their combination and proportions can be freely selected.

Examples of the composition (IV) include those having one or both of the polymer (a1) and the compound (a2). When the composition (IV) contains the compound (a2), the composition (IV) preferably further contains the polymer (b) having no energy ray-curable group as well, and in this case, the composition (IV) preferably further contains the polymer (a1) as well. Further, the composition (IV) may contain no compound (a2) described above but contain both the polymer (a1) and the polymer (b) having no energy ray-curable group.

When the composition (IV) contains the polymer (a1), the compound (a2), and the polymer (b) having no energy ray-curable group, the content of the compound (a2) in the composition (IV) is preferably from 10 to 400 parts by mass and more preferably from 30 to 350 parts by mass per 100 parts by mass of the total content of the polymer (a1) and the polymer (b) having no energy ray-curable group.

The proportion of the total content of the energy ray-curable component (a) and the polymer (b) having no energy ray-curable group to the total mass of the energy ray-curable first protective membrane forming film in the energy ray-curable first protective membrane forming film is preferably from 5 to 90 mass %, more preferably from 10 to 80 mass %, and particularly preferably from 20 to 70 mass %. When the proportion is in such a range, the energy ray curability of the energy ray-curable first protective membrane forming film further improves.

### [Filler]

Adjusting the amount of the filler in the composition (IV) and the energy ray-curable first protective membrane forming film makes it possible to adjust the effect of preventing the energy ray-curable first protective membrane forming film from remaining on the upper portion of the bump when the energy ray-curable first protective membrane forming film is attached to the bump-formed surface. In addition, the thermal expansion coefficient of the cured product (for example, the first protective membrane) of the energy ray-curable first protective membrane forming film can be more easily adjusted, and for example, by optimizing the thermal expansion coefficient of the first protective membrane with respect to the object on which the first protective membrane is to be formed, the reliability of the package produced using the energy ray-curable first protective membrane forming film further improves. In addition, as described later, to form the first protective membrane not only on the bump-formed surface of the semiconductor chip but also on a side surface of the semiconductor chip, the degree of filling can be adjusted when the first protective membrane forming film is filled in a groove provided on the bump-formed surface of the semiconductor wafer. In addition, the energy ray-curable first protective membrane forming film containing the filler makes it possible to reduce the moisture absorption rate of the cured product (for example, the first protective membrane) of the energy ray-curable first protective membrane forming film or improve the heat dissipation property.

The filler contained in the composition (IV) and the energy ray-curable first protective membrane forming film is the same as the filler (D) contained in the composition (III) and the thermosetting first protective membrane forming film described above.

The aspect of the content of the filler in the composition (IV) and the energy ray-curable first protective membrane forming film may be the same as the aspect of the content of the filler (D) in the composition (III) and the thermosetting first protective membrane forming film.

The composition (IV) and the energy ray-curable first protective membrane forming film may contain only one type of the filler or two or more types of the filler, and when two or more of the filler are contained, their combination and proportions can be freely selected.

In the energy ray-curable first protective membrane forming film, the proportion of the content of the filler to the total mass of the energy ray-curable first protective membrane forming film may be, for example, from 5 to 45 mass %. When the proportion is in such a range, the effect of preventing the energy ray-curable first protective membrane forming film from remaining on the upper portion of the bump when the energy ray-curable first protective membrane forming film forming film is attached to the bump-formed surface is further enhanced, and the thermal expansion coefficient can be more easily adjusted.

### [Additive]

Adjusting the type or amount of the additive in the composition (IV) and the energy ray-curable first protective membrane forming film makes it possible to adjust the effect of preventing the energy ray-curable first protective membrane forming film from remaining on the upper portion of the bump when the energy ray-curable first protective membrane forming film is attached to the bump-formed surface.

The additives contained in the composition (IV) and the energy ray-curable first protective membrane forming film are the same as the additives (I) contained in the composition (III) and the thermosetting first protective membrane forming film described above.

Examples of preferable additives from the viewpoint of more easily adjusting the effect of preventing the remaining of the above-described energy ray-curable first protective membrane forming film include a rheology control agent, a surfactant, and silicone oil.

The aspect of the content of the additive in the composition (IV) and the energy ray-curable first protective membrane forming film may be the same as the aspect of the content of the additive (I) in the composition (III) and the thermosetting first protective membrane forming film.

The composition (IV) and the energy ray-curable first protective membrane forming film may contain only one type of the additive or two or more types of the additive, and when two or more types of the additive are contained, their combination and proportions can be freely selected.

The content of the additive in the composition (IV) and the energy ray-curable first protective membrane forming film is not particularly limited, and can be appropriately adjusted according to the type and purpose.

For example, when the purpose is to adjust the effect of preventing the remaining of the above-described energy ray-curable first protective membrane forming film, the proportion of the content of the additive to the total mass of the energy ray-curable first protective membrane forming film in the energy ray-curable first protective membrane forming film may be, for example, from 0.5 to 10 mass %.

### [Additional Component]

The composition (IV) and the energy ray-curable first protective membrane forming film may contain additional components that do not correspond to any of the energy ray-curable component (a), the filler, the additive, and the polymer (b) having no energy ray-curable group as long as the effect of the present invention is not impaired.

Examples of the additional component include a thermosetting component, a photopolymerization initiator, a coupling agent, and a cross-linking agent. For example, the composition (IV) containing the energy ray-curable component (a) and the thermosetting component improves the adhesive strength of the energy ray-curable first protective membrane forming film to the adherend when heated, and thereby the strength of the cured product (for example, the first protective membrane) of the energy ray-curable first protective membrane forming film also improves.

Examples of the thermosetting component, the photopolymerization initiator, the coupling agent, and the cross-linking agent in the composition (IV) include the same as those of the thermosetting component (B), the photopolymerization initiator, the coupling agent (E), and the cross-linking agent (F) in the composition (III), respectively.

The composition (IV) and the energy ray-curable first protective membrane forming film may contain only one type of the additional component or two or more types of the additional component, and when two or more types of the additional component are contained, their combination and proportions can be freely selected.

The contents of the additional component in the composition (IV) and the energy ray-curable first protective membrane forming film are not particularly limited, and may be appropriately selected according to the purpose.

### [Solvent]

The composition (IV) preferably further contains a solvent. The composition (IV) containing a solvent has good handleability.

Examples of the solvent contained in the composition (TV) include the same solvents as those contained in the composition (III) described above.

The composition (IV) may contain only one type of the solvent or two or more types of the solvent, and when two or more types of the solvent are contained, their combination and proportions can be freely selected.

The content of the solvent in the composition (IV) is not particularly limited and is appropriately selected, for example, according to the types of components other than the solvent.

From the viewpoint that an intended effect of the present invention (high-speed attachment of the first protective membrane forming sheet and penetrability of the first protective membrane forming film to be described later) is further enhanced, a preferable example of the energy ray-curable first protective membrane forming film includes an energy ray-curable first protective membrane forming film containing an energy ray-curable component (a), a filler, and an additive, in which the proportion of the total content of the energy ray-curable component (a), the filler, and the additive to the total mass of the energy ray-curable first protective membrane forming film in the energy ray-curable first protective membrane forming film is 85 mass % or more, preferably 90 mass % or more, and more preferably 95 mass % or more.

In the above point, a more preferable example of the energy ray-curable first protective membrane forming film includes an energy ray-curable first protective membrane forming film containing an energy ray-curable component (a), a polymer (b) not having an energy ray-curable group, a filler, and an additive, in which the energy ray-curable component (a) is any one or both of a polymer (a1) having an energy ray-curable group and having a weight average molecular weight from 80000 to 2000000 and a compound (a2) having an energy ray-curable group and having a molecular weight from 100 to 80000, the polymer (b) not having an energy ray-curable group is one or two or more selected from the group consisting of an acrylic polymer, a phenoxy resin, a urethane resin, a polyester, a rubber-based resin, and an acrylic urethane resin, and the additive is one or two or more selected from the group consisting of a rheology control agent, a surfactant, and a silicone, and the proportion of the total content of the energy ray-curable component (a), the polymer (b) having no energy ray-curable group, the filler, and the additive to the total mass of the energy ray-curable first protective membrane forming film in the energy ray-curable first protective membrane forming film is 85 mass % or more, preferably 90 mass % or more, and more preferably 95 mass % or more.

The thickness of the energy ray-curable first protective membrane forming film is preferably from 2 to 7 times, more preferably from 3 to 6 times the thickness of the intermediate release layer.

### <Method for Manufacturing Composition for Energy Ray-Curable First Protective Membrane>

The composition for the energy ray-curable first protective membrane such as the composition (IV) is produced by blending components for forming the energy ray-curable composition.

The composition for the energy ray-curable first protective membrane can be produced, for example, by the same method as in the case of the composition for forming the thermosetting first protective membrane described above except that the types of the blending components are different.

### Non-Curable First Protective Membrane Forming Film

Examples of the non-curable first protective membrane forming film include a film containing a thermoplastic resin, a filler, and an additive.

### <Composition (V) for Forming Non-Curable First Protective Membrane>

Examples of the composition for forming the non-curable first protective membrane include a composition (V) for forming the non-curable first protective membrane (in the present specification, may be simply abbreviated as “composition (V)”) containing a thermoplastic resin, a filler, and an additive.

### [Thermoplastic Resin]

The thermoplastic resin is not particularly limited.

More specific examples of the thermoplastic resin include the same resins as non-curable resins such as polyvinyl acetal, an acrylic resin, a urethane resin, a phenoxy resin, a silicone resin, and a saturated polyester resin mentioned as the component contained in the composition (III).

The composition (V) and the non-curable first protective membrane forming film may contain only one type of the thermoplastic resin or two or more types of the thermoplastic resin, and when two or more types of the thermoplastic resin are contained, their combination and proportions can be freely selected.

The proportion of the content of the thermoplastic resin to the total mass of the non-curable first protective membrane forming film in the non-curable first protective membrane forming film is preferably from 25 to 75 mass %.

### [Filler]

The non-curable first protective membrane forming film containing the filler has the same effect as that of the thermosetting first protective membrane forming film containing the filler (D).

Examples of the filler contained in the composition (V) and the non-curable first protective membrane forming film include the same fillers as those of the filler (D) contained in the composition (I) and the thermosetting first protective membrane forming film.

The composition (V) and the non-curable first protective membrane forming film may contain only one type of the filler, or two or more types of the filler. When two or more types of the filler are contained, their combination and proportions can be freely selected.

The proportion of the content of the filler to the total mass of the non-curable first protective membrane forming film in the non-curable first protective membrane forming film is preferably from 15 to 70 mass %. When the proportion is in such a range, as in the case of using the composition (III), the effect of preventing the non-curable first protective membrane forming film from remaining on the upper portion of the bump when the non-curable first protective membrane forming film is attached to the bump-formed surface is further enhanced, and the thermal expansion coefficients of the non-curable first protective membrane forming film and the first protective membrane are more easily adjusted. In addition, as described later, it is possible to sufficiently fill the groove provided on the bump-formed surface of the semiconductor wafer with the non-curable first protective membrane forming film to form the first protective membrane not only on the bump-formed surface but also on a side surface of the semiconductor chip.

### [Additive]

Adjusting the type or amount of the additive in the composition (V) and the non-curable first protective membrane forming film makes it possible to adjust the effect of preventing the non-curable first protective membrane forming film from remaining on the upper portion of the bump when the non-curable first protective membrane forming film is attached to the bump-formed surface.

The additive contained in the composition (V) and the non-curable first protective membrane forming film are the same as the additives (I) contained in the composition (III) and the thermosetting first protective membrane forming film described above.

From the viewpoint that the effect of preventing the remaining of the non-curable first protective membrane forming film can be more easily adjusted, examples of preferable additives include a rheology control agent, a surfactant, and a silicone oil.

The aspect of the content of the additive in the composition (V) and the non-curable first protective membrane forming film may be the same as the aspect of the content of the additive (I) in the composition (III) and the thermosetting first protective membrane forming film.

The composition (V) and the non-curable first protective membrane forming film may contain only one type of the additive or two or more types of the additive, and when two or more types of the additive are contained, their combination and proportions can be freely selected.

The content of the additive in the composition (V) and the non-curable first protective membrane forming film is not particularly limited, and can be appropriately adjusted according to the type and purpose.

For example, when the purpose is to adjust the effect of preventing the non-curable first protective membrane forming film from remaining, the proportion of the content of the additive to the total mass of the non-curable first protective membrane forming film in the non-curable first protective membrane forming film may be, for example, from 0.5 to 10 mass %.

### [Additional Component]

The composition (V) and the non-curable first protective membrane forming film may contain additional components that do not correspond to any of the thermoplastic resin, the filler, and the additive as long as the effects of the present invention are not impaired.

The additional components are not particularly limited and may be freely selected depending on the intended purpose.

The composition (V) and the non-curable first protective membrane forming film may contain only one type of the additional component or two or more types of the additional component, and when two or more types of the additional component are contained, their combination and proportions can be freely selected.

The content of the additional component in the composition (V) and the non-curable first protective membrane forming film is not particularly limited, and may be appropriately selected according to the purpose.

### [Solvent]

The composition (V) preferably further contains a solvent. The composition (V) containing a solvent has good handleability.

Examples of the solvent contained in the composition (V) include the same solvents as those contained in the composition (III) described above.

The composition (V) may contain only one type of the solvent or two or more types of the solvent, and when two or more types of the solvent are contained, their combination and proportions can be freely selected.

The content of the solvent in the composition (V) is not particularly limited and is appropriately selected, for example, according to the types of components other than the solvent.

From the viewpoint that an intended effect of the present invention (high-speed attachment of the first protective membrane forming sheet and penetrability of the first protective membrane forming film to be described later) is further enhanced, a preferable example of the non-curable first protective membrane forming film includes a non-curable first protective membrane forming film containing a thermoplastic resin, a filler, and an additive, in which the proportion of the total content of the thermoplastic resin, the filler, and the additive to the total mass of the non-curable first protective membrane forming film in the non-curable first protective membrane forming film is 85 mass % or more, preferably 90 mass % or more, and more preferably 95 mass % or more.

In view of the above, a more preferable example of the non-curable first protective membrane forming film includes a non-curable first protective membrane forming film containing the thermoplastic resin, the filler, and the additive, in which the thermoplastic resin is one or two or more selected from the group consisting of a polyvinyl acetal, an acrylic resin, a urethane resin, a phenoxy resin, a silicone resin, and a saturated polyester resin, the additive is one or two or more selected from the group consisting of a rheology control agent, a surfactant, and a silicone oil, and the proportion of the total content of the thermoplastic resin, the filler, and the additive to the total mass of the non-curable first protective membrane forming film in the non-curable first protective membrane forming film is 85 mass % or more, preferably 90 mass % or more, and more preferably 95 mass % or more.

The thickness of the non-curable first protective membrane forming film is preferably from 2 to 7 times, more preferably from 3 to 6 times the thickness of the intermediate release layer.

### <Method for Manufacturing Composition for Forming Non-Curable First Protective Membrane>

The composition for forming the non-curable first protective membrane such as the composition (V) is produced by blending components for forming the composition.

The non-curable composition for forming the first protective membrane can be manufactured, for example, by the same method as in the case of the composition for forming the thermosetting first protective membrane described above except that the types of the blending components are different.

### Intermediate Release Layer

The intermediate release layer, containing EVA, improves the embedding property of the bump of the first protective membrane forming film when the first protective membrane forming sheet is attached to the bump-formed surface of a semiconductor wafer. This makes it possible to perform high-speed attachment of the first protective membrane forming sheet to the bump-formed surface of the semiconductor wafer. In the present specification, when the first protective membrane forming sheet can be attached at a high speed as described above, such characteristic may be referred to as “high-speed attachment property”.

Further, the intermediate release layer, containing EVA, realizes strong push of the first protective membrane forming film with the buffer layer when the first protective membrane forming sheet is attached to the bump-formed surface of a semiconductor wafer. This allows the top portion of the bump to protrude from the first protective membrane forming film and prevents the first protective membrane forming film from remaining on the upper portion of the bump even when the first protective membrane forming sheet is attached at a high speed. In the present specification, when the first protective membrane forming film in the first protective membrane forming sheet is prevented from remaining on the upper portion of the bump and the top portion of the bump easily protrudes, such characteristic may be referred to as “penetrability”.

Since EVA has a property of appropriately softening at the time of heating, these effects, that is, the effect that the first protective membrane forming sheet has a high-speed attachment property and the first protective membrane forming film has a penetrability are remarkably exhibited particularly when the first protective membrane forming sheet is attached while being heated.

Since the first protective membrane forming sheet of the present embodiment includes the intermediate release layer, the above-described excellent effect is exhibited without depending on the type of the first protective membrane forming film.

The intermediate release layer contains the ethylene-vinyl acetate copolymer (EVA), and may contain only the ethylene-vinyl acetate copolymer (in other words, it may be a layer composed of an ethylene-vinyl acetate copolymer), or may contain the ethylene-vinyl acetate copolymer and additional components.

The intermediate release layer has a sheet shape or a film shape.

The intermediate release layer may be formed only one layer (single layer), or may be formed of a plurality of layers of two or more layers. When the intermediate release layer is formed of a plurality of layers, the plurality of layers may be the same or different from each other, and a combination of the plurality of layers is not particularly limited.

The thickness of the intermediate release layer is preferably from 5 to 30 μm, more preferably from 6 to 25 μm, and particularly preferably from 7 to 20 μm.

Here, the “thickness of the intermediate release layer” means the thickness of the entire intermediate release layer, and for example, the thickness of the intermediate release layer formed of a plurality of layers means the total thickness of all the layers constituting the intermediate release layer.

### <<Composition for Forming Intermediate Release Layer>>

The intermediate release layer can be formed using a composition for forming the intermediate release layer containing the constituent material. For example, the intermediate release layer can be formed by coating the composition for forming the intermediate release layer onto the surface on which the intermediate release layer is to be formed, and drying the composition as necessary. A more specific method for forming the intermediate release layer will be described in detail later together with a method for forming other layers. The ratio of the contents of the components that are not vaporized at normal temperature in the composition for forming the intermediate release layer is usually the same as the ratio of the contents of the components in the intermediate release layer.

In the intermediate release layer, the proportion of the total content of one or two or more components to be described later in the intermediate release layer to the total mass of the intermediate release layer does not exceed 100 mass %.

Also in the composition for forming the intermediate release layer, the proportion of the total content of one or two or more components to be described later in the composition for forming the intermediate release layer to the total mass of the composition for forming the intermediate release layer does not exceed 100 mass %.

The composition for forming the intermediate release layer can be coated by the same method as in the case of the composition for forming the first protective membrane described above.

The drying conditions of the composition for forming the intermediate release layer are not particularly limited. However, when the composition for forming the intermediate release layer contains a solvent to be described later, it is preferable to heat and dry the composition. The composition for forming the intermediate release layer containing a solvent is preferably heated and dried at 70 to 130° C. for 10 seconds to 5 minutes, for example.

### <Composition for Forming Intermediate Release Layer (VII)>

Examples of the composition for forming the intermediate release layer include a composition for forming the intermediate release layer (VII) (in the present specification, it may be simply referred to as a “composition (VII)”) containing an ethylene-vinyl acetate copolymer (EVA).

The composition (VII) may contain an ethylene-vinyl acetate copolymer and additional components.

In the ethylene-vinyl acetate copolymer, the proportion of the amount (parts by mass) of the constituent units derived from vinyl acetate to the total amount of the constitutional units (the total amount of all the constitutional units constituting the ethylene-vinyl acetate copolymer. Hereinafter, the same applies) (parts by mass) [amount of constitutional unit derived from vinyl acetate constituting ethylene-vinyl acetate copolymer (parts by mass)]/[total amount (parts by mass) of all constituent units constituting ethylene-vinyl acetate copolymer]×100) is preferably 16 mass % or more, more preferably 17.5 mass % or more, and still more preferably 19 mass % or more, and it may be, for example, either 25 mass % or more or 30 mass % or more. When the proportion is more than or equal to the lower limit value, the high-speed attachment property of the first protective membrane forming sheet and the penetrability of the first protective membrane forming film further improve.

In the present specification, the proportion of the amount (parts by mass) of the constitutional unit derived from vinyl acetate to the total amount (parts by mass) of the constitutional units in the ethylene-vinyl acetate copolymer may be referred to as “VA content”.

In the ethylene-vinyl acetate copolymer, the proportion (VA content) of the amount (parts by mass) of the constitutional unit derived from vinyl acetate to the total amount (parts by mass) of the constitutional units is preferably 40 mass % or less, more preferably 37 mass % or less, and still more preferably 34 mass % or less, and it may be, for example, either 30 mass % or less or 25 mass % or less. When the proportion is less than or equal to the upper limit value, the handleability of the composition (VII) further improves, and the first protective membrane forming film can be more easily formed.

In the ethylene-vinyl acetate copolymer, the proportion (VA content) of the amount (parts by mass) of the constitutional unit derived from vinyl acetate to the total amount (parts by mass) of the constitutional units can be appropriately adjusted within a range set by freely combining any of the above-described lower limit values and any of the above-described upper limit values. For example, the proportion is preferably from 16 to 40 mass %, more preferably from 17.5 to 37 mass %, and still more preferably from 19 to 34 mass %, and it may be, for example, either from 25 to 34 mass % or from 30 to 34 mass %, or either from 19 to 30 mass % or from 19 to 25 mass %. However, these are examples of the proportion.

The weight average molecular weight of the ethylene-vinyl acetate copolymer is preferably 200000 or less, more preferably 180000 or less, and still more preferably 160000 or less, and it may be, for example, either 100000 or less or 60000 or less. When the weight average molecular weight is less than or equal to the upper limit value, the high-speed attachment property of the first protective membrane forming sheet and the penetrability of the first protective membrane forming film further improves.

The lower limit of the weight average molecular weight of the ethylene-vinyl acetate copolymer is not particularly limited. For example, from the viewpoint that the membrane formability of the composition (VII) is further enhanced, the weight average molecular weight may be 5000 or more.

The weight average molecular weight of the ethylene-vinyl acetate copolymer may be, for example, from 5000 to 200000, from 5000 to 180000, from 5000 to 160000, from 5000 to 100000, or from 5000 to 60000. However, these are examples of the weight average molecular weight.

The ethylene-vinyl acetate copolymer is preferably a main component of the intermediate release layer. This further improves the high-speed attachment property of the first protective membrane forming sheet and the penetrability of the first protective membrane forming film.

In particular, in the intermediate release layer, the proportion of the content of the ethylene-vinyl acetate copolymer to the total mass of the intermediate release layer ([content (parts by mass) of ethylene-vinyl acetate copolymer in intermediate release layer]/[total mass (parts by mass) of intermediate release layer]×100) is preferably 80 mass % or more, more preferably 90 mass % or more, and it may be, for example, 95 mass % or more, 97 mass %, or 99 mass % or more. When the proportion is more than or equal to the lower limit value, the high-speed attachment property of the first protective membrane forming sheet and the penetrability of the first protective membrane forming film further improves.

The proportion is 100 mass % or less.

### [Additional Component]

The additional component contained in the composition (VII) and the intermediate release layer is not particularly limited, and can be appropriately selected according to the purpose.

The composition (VII) and the intermediate release layer may contain only one type of the additional component or two or more types of the additional component, and when two or more types of the additional component are contained, their combination and proportions can be freely selected.

Examples of the additional component contained in the composition (VII) and the intermediate release layer include a nonpolar resin such as an ethylene-based polymer.

The ethylene-based polymer is a polymer having at least a constituent unit derived from ethylene, and may be a homopolymer of ethylene or a copolymer of ethylene and another monomer.

Examples of the homopolymer of ethylene (that is, polyethylene) include low density polyethylene (LDPE), linear low density polyethylene (LLDPE), metallocene-catalyzed linear low density polyethylene (mLLDPE), medium density polyethylene (MDPE), and high density polyethylene (HDPE).

The non-polar resin such as the ethylene-based polymer may be an oily component such as paraffin oil or paraffin wax.

Examples of the additional component contained in the composition (VII) include a solvent. The composition (VII) containing a solvent is excellent in handleability.

Examples of the solvent contained in the composition (VII) include a hydrocarbon such as toluene and xylene; an alcohol such as methanol, ethanol, 2-propanol, isobutyl alcohol (2-methylpropane-1-ol), and 1-butanol; an ester such as ethyl acetate; a ketone such as acetone and methyl ethyl ketone; an ether such as tetrahydrofuran; and an amide (a compound having an amide bond) such as dimethylformamide and N-methylpyrrolidone.

The composition (VII) may contain only one type or two or more types of the solvent. When two or more types of the solvent are contained, their combination and proportions can be freely selected.

The contents of the additional component in the composition (VII) and the intermediate release layer can be appropriately adjusted according to the type of the additional component.

When the additional component is a component other than the solvent, the proportion of the content of the additional component (component other than the solvent) to the total mass of the intermediate release layer in the intermediate release layer ([content (parts by mass) of the additional component other than the solvent in the intermediate release layer]/[total mass (parts by mass) of intermediate release layer]×100) is preferably 20 mass % or less, more preferably 10 mass % or less, and it may be, for example, 5 mass % or less, 3 mass % or less, or 1 mass % or less. When the proportion is less than or equal to the upper limit value, the high-speed attachment property of the first protective membrane forming sheet and the penetrability of the first protective membrane forming film further improves.

When the additional component is a component other than the solvent, the proportion is 0 mass % or more.

When the additional component is a solvent, the proportion of the content of the additional component (solvent) to the total mass of the composition (VII) in the composition (VII) ([content (parts by mass) of solvent in composition (VII)]/[total mass (parts by mass) of composition (VII)]×100) is preferably from 5 to 50 mass %, and it may be, for example, either from 5 to 35 mass % or from 5 to 20 mass %. When the proportion is more than or equal to the lower limit value, the handleability of the composition (VII) further improves. When the property is less than or equal to the upper limit value, the first protective membrane forming film can be formed more efficiently.

From the viewpoint that the intended effect of the present invention (the high-speed attachment property of the first protective membrane forming sheet and the penetrability of the first protective membrane forming film) is further enhanced, a preferable example of the intermediate release layer includes an intermediate release layer containing an ethylene-vinyl acetate copolymer, in which in the intermediate release layer, the proportion of the content of the ethylene-vinyl acetate copolymer to the total mass of the intermediate release layer is 80 mass % or more, and preferably 90 mass % or more, and in the ethylene-vinyl acetate copolymer, the proportion of the amount of a constitutional unit derived from vinyl acetate to the total amount of constitutional units is from 16 to 40 mass %, and the weight average molecular weight of the ethylene-vinyl acetate copolymer is 200000 or less.

### <<Method for Manufacturing Composition for Forming Intermediate Release Layer>>

The composition for forming the intermediate release layer such as the composition (VII) is produced by blending components for forming the composition.

The composition for forming the intermediate release layer can be manufactured, for example, by the same method as in the case of the composition for forming the thermosetting first protective membrane described above except that the types of the blending components are different.

### Buffer Layer

The buffer layer has a buffering action against a force applied to the buffer layer and a layer in the vicinity thereof. Here, the “layer near the buffer layer” includes the intermediate release layer, the first protective membrane forming film, and the first protective membrane.

A constituent material of the buffer layer is not particularly limited, but is preferably a resin.

Preferable examples of the buffer layer include a buffer layer formed using a composition for forming the buffer layer containing urethane (meth)acrylate or the like.

The buffer layer may be formed of only one layer (single layer), or may be formed of a plurality of layers of two or more layers. When the buffer layer is formed of a plurality of layers, the plurality of layers may be the same or different from each other, and a combination of the plurality of layers is not particularly limited.

The thickness of the buffer layer is preferably from 150 to 1000 μm, more preferably from 150 to 800 μm, still more preferably from 200 to 600 μm, and particularly preferably from 250 to 500 μm.

Here, the “thickness of the buffer layer” means the thickness of the entire buffer layer, and for example, the thickness of the buffer layer formed of a plurality of layers means the total thickness of all the layers constituting the buffer layer.

### <<Composition for Forming Buffer Layer>>

The buffer layer can be formed using a composition for forming the buffer layer containing a material for forming the buffer layer. For example, the buffer layer can be formed by coating the composition for forming the buffer layer to the surface on which the buffer layer is to be formed and drying the composition as necessary. When the composition for forming the buffer layer has energy ray curability as described later, it is preferable to further cure the coated composition for forming the buffer layer with energy rays. A more specific method for forming the buffer layer will be described in detail later together with a method for forming other layers.

In the composition for forming the buffer layer, the proportion of the total content of one or two or more components to be described later in the composition for forming the buffer layer to the total mass of the composition for forming the buffer layer does not exceed 100 mass %.

The composition for forming the buffer layer can be coated by the same method as in the case of the composition for forming the first protective membrane described above.

The drying conditions of the composition for forming the buffer layer are not particularly limited, and may be, for example, the same as the drying conditions of composition for forming the intermediate release layer described above.

When the composition for forming the energy ray-curable buffer layer is energy ray-cured, the illuminance of the energy ray is preferably from 100 to 350 mW/cm², and the light amount of the energy ray is preferably from 200 to 1400 mJ/cm². The energy ray curing of the composition for forming the energy ray-curable buffer layer may be performed once, or may be performed two or more times (via semi-curing). When the energy ray curing is performed in a plurality of times, the light amount of the energy ray is preferably from 200 to 1400 mJ/cm² in all the times, and the total light amount in all the times is preferably from 200 to 1400 mJ/cm².

### <Composition for Forming Buffer Layer (VI)>

Examples of the composition for forming the buffer layer include a composition (VI) for forming the buffer layer (in the present specification, it may be simply referred to as “composition (VI)”) containing a urethane (meth)acrylate (X).

### [Urethane (Meth)Acrylate (X)]

The urethane (meth)acrylate (X) contained in the composition (VI) is a compound having at least a (meth)acryloyl group and a urethane bond, and has a property of being polymerized through energy ray irradiation. That is, the composition (VI) has energy ray curability. The number of (meth)acryloyl groups in the urethane (the number of meth acrylate (X) may be any one of 1, 2, and 3 or more (that is, the urethane (meth)acrylate (X) may be any of monofunctional, bifunctional, and trifunctional or higher functional), but is preferably a monofunctional urethane (meth)acrylate (X). Since the monofunctional urethane (meth)acrylate (X) is not involved in the formation of the three-dimensional network structure in the polymerized structure, the three-dimensional network structure is hardly formed in the buffer layer, and in this case, the first protective membrane forming sheet easily follows the bump-formed surface of a semiconductor wafer.

The composition (VI) may contain one type or two or more types of the urethane (meth)acrylate (X), and when two or more types of the urethane (meth)acrylate (X) are contained, their combination and proportions can be freely selected.

Examples of the urethane (meth)acrylate (X) include a reaction product of a terminal isocyanate urethane prepolymer, which is a reaction product of a polyol compound (x1) and a polyisocyanate compound (x2), and a compound (x3) having a (meth)acryloyl group. Here, the “terminal isocyanate urethane prepolymer” is as described above.

The polyol compound (x1) is not particularly limited as long as it is a compound having two or more hydroxyl groups per molecule thereof.

Examples of the polyol compound (x1) include an alkylene diol, a polyether polyol, a polyester polyol, and a polycarbonate polyol. Among them, the polyol compound (x1) is preferably a polyether polyol.

The polyol compound (x1) may be a bifunctional diol, a trifunctional triol, and a tetrafunctional or higher polyol, but is preferably a bifunctional diol and more preferably a polyether diol from the viewpoint of easy availability, versatility, reactivity, and the like.

Examples of the polyether diol include polyethylene glycol, polypropylene glycol, and polytetramethylene glycol.

The polyester polyol is produced through polycondensation reaction of a polyol component and a polybasic acid component. Examples of the polyol component include various alkanediols (preferably, an alkanediol having from 2 to 10 carbons) such as ethylene glycol, diethylene glycol, and butanediol, and various glycols.

Examples of the polybasic acid component include components known as polybasic acid components of normal polyesters. More specifically, examples of the polybasic acid component include an aliphatic dibasic acid having from 4 to 20 carbons such as adipic acid and sebacic acid; an aromatic dibasic acid such as terephthalic acid; an aromatic polybasic acid such as trimellitic acid; an anhydride of these di- or polybasic acids; a derivative of these di- or polybasic acids, dimer acids, and hydrogenated dimer acids.

The polycarbonate polyol is not particularly limited. Examples of the polycarbonate polyol include a reaction product of glycols and alkylene carbonate.

Examples of the polyisocyanate compound (x2) include an aliphatic polyisocyanate, an alicyclic polyisocyanate, and an aromatic polyisocyanate.

Examples of the compound (x3) having a (meth)acryloyl group include a (meth)acrylate having a hydroxyl group, and examples thereof include the same hydroxyl group-containing (meth)acrylate as those described above as those constituting the acrylic resin as the polymer component (A) which is a component contained in the composition (III).

Among them, the (meth)acrylate having a hydroxyl group is preferably a hydroxyalkyl (meth)acrylate.

The weight average molecular weight of the urethane (meth)acrylate (X) is preferably from 1000 to 100000, more preferably from 3000 to 80000, and still more preferably from 5000 to 65000. When the weight average molecular weight is 1000 or more, moderate hardness is imparted to the buffer layer by a polymer of the urethane (meth)acrylate (X) and the polymerizable monomer (Z) described later.

The proportion of the content of the urethane (meth)acrylate (X) to the total content of components other than the solvent in the composition (VI) ([content (parts by mass) of urethane (meth)acrylate (X) in composition (VI)]/[total content (parts by mass) of components other than solvent in composition (VI)]×100) is preferably from 10 to 70 mass %, more preferably from 20 to 70 mass %, still more preferably from 25 to 60 mass %, and particularly preferably from 30 to 50 mass %. When the proportion is in such a range, the effect achieved by the buffer layer in the first protective membrane forming sheet further improves without impairing other effects.

### [Additional Component]

The composition (VI) may contain the urethane (meth)acrylate (X) and additional components not corresponding to the urethane (meth)acrylate (X).

Examples of the additional component in the composition (VI) include a thiol group-containing compound (Y) and a polymerizable monomer (Z).

The composition (VI) may contain one type or two or more types of the additional component, and when the two or more types of the additional component are contained, their combination and proportions can be freely selected.

The composition (VI) may contain either the thiol group-containing compound (Y) or the polymerizable monomer (Z), but preferably contains both the thiol group-containing compound (Y) and the polymerizable monomer (Z).

### (Thiol Group-Containing Compound (Y))

The thiol group-containing compound (Y) is not particularly limited as long as it is a compound having one or two or more thiol groups (—SH) per molecule thereof.

Examples of the thiol group-containing compound (Y) include nonylmercaptan, 1-dodecanethiol, 1,2-ethanedithiol, 1,3-propanedithiol, triazinethiol, triazinedithiol, triazinetrithiol, 1,2,3-propanetrithiol, tetraethylene glycol-bis(3-mercaptopropionate), trimethylolpropane tris(3-mercaptopropionate), pentaerythritol tetrakis(3-mercaptopropionate), pentaerythritol tetrakisglycolate, dipentaerythritol hexakis(3-mercaptopropionate), tris[(3-mercaptopropionyloxy)-ethyl]-isocyanurate, 1,4-bis(3-mercaptobutyryloxy)butane, pentaerythritol tetrakis(3-mercaptobutythritol), and 1,3,5-tris(3-mercaptobutyloxyethyl)-1,3,5-triazine-2,4,6-(1H, 3H, 5H)-trione.

The thiol group-containing compound (Y) is preferably a polyfunctional thiol group-containing compound (compound having two or more thiol groups per molecule), and more preferably a tetrafunctional thiol group-containing compound (compound having four thiol groups per molecule).

The composition (VI) may contain one type or two or more types of the thiol group-containing compound (Y), and two or more types of the thiol group-containing compound (Y) are contained, their combination and proportions can be freely selected.

The proportion of the thiol group-containing compound (Y) with respect to 100 parts by mass of the total content of the urethane (meth)acrylate (X) and the polymerizable monomer (Z) in the composition (VI) ([content (parts by mass) of thiol group-containing compound (Y) in composition (VI)]/[total content (parts by mass) of urethane (meth)acrylate (X) and polymerizable monomer (Z) in composition (VI)]×100) is preferably from 1 to 4.9 parts by mass, and more preferably from 1.5 to 4.8 parts by mass.

### (Polymerizable Monomer (Z))

The composition (VI) preferably contains a polymerizable monomer (Z) from the viewpoint of improving the membrane formability of the buffer layer. The polymerizable monomer (Z) is a polymerizable compound other than the urethane (meth)acrylate (X), and is a compound that can be polymerized by irradiation with an energy ray. However, the polymerizable monomer (Z) does not contain a resin component. Here, the “resin component” means a compound which is an oligomer or polymer having a repeating structure in its structure, and having a weight average molecular weight of 1000 or more.

The polymerizable monomer (Z) is preferably a compound having one or two or more (meth)acryloyl groups. Examples of such a polymerizable monomer (Z) include an alkyl (meth)acrylate in which an alkyl group constituting the alkyl ester has a chain structure having from 1 to 18 carbons; a (meth)acrylate having a functional group such as a hydroxyl group, an amide group, an amino group, or an epoxy group; a (meth)acrylate having an alicyclic structure such as cycloalkyl (meth)acrylate; a (meth)acrylate having an aromatic structure; a (meth)acrylate having a heterocyclic structure; and vinyl compounds other than these.

Among the (meth)acrylates having a functional group, examples of the (meth)acrylate having a hydroxyl group include the same hydroxyl group-containing (meth)acrylates as those mentioned above as those constituting the acrylic resin as the polymer component (A) which is a component contained in the composition (III).

Examples of the (meth)acrylate having an alicyclic structure include isobornyl (meth)acrylate, dicyclopentenyl (meth)acrylate, dicyclopentanyl (meth)acrylate, dicyclopentenyloxy (meth)acrylate, cyclohexyl (meth)acrylate, 1-adamantyl (meth)acrylate, and 2-adamantyl (meth)acrylate.

Examples of the (meth)acrylate having an aromatic structure include phenylhydroxypropyl (meth)acrylate, benzyl (meth)acrylate, and 2-hydroxy-3-phenoxypropyl (meth)acrylate.

Examples of the (meth)acrylate having a heterocyclic structure include tetrahydrofurfuryl (meth)acrylate and 2-morpholinoethyl (meth)acrylate.

The composition (VI) may contain one type or two or more types of the polymerizable monomer (Z), and when two or more types of the polymerizable monomer (Z) are contained, their combination and proportions can be freely selected.

The composition (VI) preferably contains, as the polymerizable monomer (Z), at least the (meth)acrylate having an alicyclic structure, more preferably contains both the (meth)acrylate having an alicyclic structure and the (meth)acrylate having a functional group, and still more preferably contains both isobornyl (meth)acrylate and hydroxyalkyl (meth)acrylate.

The proportion of the content of the polymerizable monomer (Z) to the total content of components other than the solvent in the composition (VI) ([content (parts by mass) of polymerizable monomer (Z) in composition (VI)]/[total content (parts by mass) of components other than solvent in composition (VI)]×100) is preferably from 20 to 80 mass %, more preferably from 30 to 80 mass %, still more preferably from 40 to 75 mass %, and particularly preferably from 50 to 70 mass %. When the content is in such a range, the mobility of a portion having a structure in which the polymerizable monomer (Z) is polymerized in the buffer layer becomes higher, and thus the buffer layer tends to be more flexible, and the first protective membrane forming sheet more easily follows the bump-formed surface of a semiconductor wafer.

The proportion of the content of the (meth)acrylate having an alicyclic structure to the total content of the polymerizable monomer (Z) in the composition (VI) ([content (parts by mass) of (meth)acrylate having an alicyclic structure in composition (VI)]/[total content (parts by mass) of polymerizable monomer (Z) in composition (VI)]×100) is preferably from 52 to 87 mass %, more preferably from 55 to 85 mass %, and still more preferably from 60 to 80 mass %. When the content is in such a range, the first protective membrane forming sheet more easily follows the bump-formed surface of a semiconductor wafer.

The mass ratio of [content (parts by mass) of urethane (meth)acrylate (X) in composition (VI)]/[content (parts by mass) of polymerizable monomer (Z) in composition (VI)] is preferably 20/80 to 60/40, more preferably 30/70 to 50/50, and still more preferably 35/65 to 45/55. When the mass ratio is in such a range, the first protective membrane forming sheet more easily follows the bump-formed surface of a semiconductor wafer.

### (Photopolymerization Initiator)

The composition (VI) preferably further contains a photopolymerization initiator. The composition (VI) containing a photopolymerization initiator is more easily cured by irradiation with energy rays.

Examples of the photopolymerization initiator contained in the composition (VI) include a low molecular weight polymerization initiator such as acetophenone, 2,2-diethoxybenzophenone, 4-methylbenzophenone, 2,4,6-trimethylbenzophenone, Michler's ketone, benzoin, benzoin methyl ether, benzoin ethyl ether, benzoin isopropyl ether, benzoin isobutyl ether, benzyl diphenysulfide, tetramethylthiuram monosulfide, benzyl dimethyl ketal, dibenzyl, diacetyl, 1-chloranthraquinone, 2-chloranthraquinone, 2-ethylanthraquinone, 2,2-dimethoxy-1, 2-diphenylethane-1-one, 1-hydroxycyclohexylphenyl ketone, 2-methyl-1-[4-(methylthio)phenyl]-2-morpholino-1-propanone, 2-benzyl-2-dimethylamino-1-(4-morpholinophenyl)-1-butanone, 2-hydroxy-2-methyl-1-phenyl-propane-1-one, diethylthioxanthone, isopropylthioxanthone, and 2,4,6-trimethylbenzoyldiphenyl-phosphine oxide; and oligomerized polymerization initiators such as oligo {2-hydroxy-2-methyl-1-[4-(1-methylvinyl)phenyl]propanone}.

The composition (VI) may contain one type or two or more types of the photopolymerization initiator, and when two or more types of the photopolymerization initiator are contained, their combination and proportions can be freely selected.

The content of the photopolymerization initiator with respect to 100 parts by mass of the total content of the urethane (meth)acrylate (X) and the polymerizable monomer (Z) in the composition (VI) ([content (parts by mass) of photopolymerization initiator of composition (VI)]/[total content (parts by mass) of urethane (meth)acrylate (X) and polymerizable monomer (Z) in composition (VI)]×100) is preferably from 0.05 to 15 parts by mass, more preferably from 0.1 to 10 parts by mass, and still more preferably from 0.3 to 5 parts by mass.

### Additional Additive

The composition (VI) may contain an additional additive that does not correspond to the components described above as long as the effects of the present invention are not impaired.

Examples of the additional additive include a cross-linking agent, an antioxidant, a softener (plasticizer), a filler, a rust inhibitor, a pigment, and a dye.

When the composition (VI) contains the additional additive, the content of the additional additive with respect to 100 parts by mass of the total content of the urethane (meth)acrylate (X) and the polymerizable monomer (Z) in the composition (VI) ([content (parts by mass) of additional additive of composition (VI)]/[total content (parts by mass) of urethane (meth)acrylate (X) and polymerizable monomer (Z) in composition (VI)]×100) is preferably from 0.01 to 6 parts by mass, and more preferably from 0.1 to 3 parts by mass.

### (Additional Resin Component)

The composition (VI) may contain an additional resin component that does not correspond to the urethane (meth)acrylate (X) as long as the effect of the present invention is not impaired.

### <Modification of Buffer Layer>

The buffer layer formed using the composition for forming the buffer layer containing the urethane (meth)acrylate (X) has been described above, but in the present embodiment, the buffer layer may be formed using a composition for forming the buffer layer containing another resin component such as an olefin-based resin instead of the urethane (meth)acrylate (X).

From the viewpoint that the intended effects of the present invention (high-speed attachment property of the first protective membrane forming sheet and penetrability of the first protective membrane forming film) are further enhanced, a preferable example of the buffer layer includes a buffer layer produced using the composition for forming the buffer layer (composition (VI)) containing a urethane (meth)acrylate (X), the thiol group-containing compound (Y), the polymerizable monomer (Z), the photopolymerization initiator, and the cross-linking agent, in which the proportion of the total content of the urethane (meth)acrylate (X), the thiol group-containing compound (Y), the polymerizable monomer (Z), the photopolymerization initiator, and the cross-linking agent to the total content of components other than the solvent in the composition for forming the buffer layer is 85 mass % or more, preferably 90 mass % or more, more preferably 95 mass % or more.

In view of the above, a more preferred example of the buffer layer includes a buffer layer produced using the composition for forming the buffer layer (composition (VI)) containing a urethane (meth)acrylate (X), the thiol group-containing compound (Y), the polymerizable monomer (Z), the photopolymerization initiator, and the cross-linking agent, in which the urethane (meth)acrylate (X) is a reaction product of a terminal isocyanate urethane prepolymer, which is a reaction product of the polyol compound (x1) and the polyisocyanate compound (x2), and the compound (x3) having a (meth)acryloyl group, the thiol group-containing compound (Y) is a polyfunctional thiol group-containing compound having two or more thiol groups per molecule thereof, and the polymerizable monomer (Z) is a (meth)acrylate having an alicyclic structure and a (meth)acrylate having a functional group, the proportion of the total content of the urethane (meth)acrylate (X), the thiol group-containing compound (Y), the polymerizable monomer (Z), the photopolymerization initiator, and the cross-linking agent to the total content of components other than the solvent in composition for forming the buffer layer is 85 mass % or more, preferably 90 mass % or more, and more preferably 95 mass % or more.

These buffer layers are preferably produced by curing the composition for forming the buffer layer with energy rays.

The thickness of these buffer layers is preferably from 10 to 70 times and more preferably from 30 to 50 times the thickness of the intermediate release layer.

### <<Method for Manufacturing Composition for Forming Buffer Layer>>

The composition for forming the buffer layer such as the composition (VI) is produced by blending components for constituting the composition for forming the buffer layer.

The composition for forming the buffer layer can be manufactured, for example, by the same method as for the composition for forming the thermosetting first protective membrane described above except that the types of components to be blended are different.

### First Base Material

The first base material has a sheet shape or a film shape, and examples of a constituent material thereof include various resins.

Examples of the resin include a polyethylene, such as a low-density polyethylene (LDPE), a linear low-density polyethylene (LLDPE), and a high-density polyethylene (HDPE); a polyolefin other than a polyethylene, such as a polypropylene, a polybutene, a polybutadiene, a polymethylpentene, and a norbornene resin; an ethylene-based copolymer (a copolymer formed using ethylene as a monomer), such as an ethylene-vinyl acetate copolymer, an ethylene-((meth)acrylic acid copolymer, an ethylene-(meth)acrylate copolymer, and an ethylene-norbornene copolymer; a vinyl chloride-based resin (a resin formed by using vinyl chloride as a monomer), such as a polyvinyl chloride and a vinyl chloride copolymer; a polystyrene; a polycycloolefin; a polyester, such as a polyethylene terephthalate, a polyethylene naphthalate, a polybutylene terephthalate, a polybutylene isophthalate, a polyethylene-2,6-naphthalane dicarboxylate, and a wholly aromatic polyester in which all the constitutional units have an aromatic cyclic group; a copolymer of two or more types of polyester described above; a polymethacrylate; a polyurethane; a polyurethane acrylate; a polyimide; a polyamide; a polycarbonate; a fluororesin; a polyacetal; a modified polyphenylene oxide; a polyphenylene sulfide; a polysulfone; and a polyether ketone.

In addition, examples of the resin also include polymer alloys, such as a mixture of the polyester described above and a resin other than the polyester. The polymer alloy of the polyester and a resin other than the polyester preferably contains a relatively small amount of the resin other than the polyester.

Furthermore, examples of the resin also include crosslinked resins in which one type or two or more types of the resin exemplified so far are crosslinked; and modified resins, such as ionomers formed using one type or two or more types of the resin exemplified so far.

Only one type or two or more types of the resin may be contained in the first base material, and when two or more types of the resin are used, their combination and proportions can be freely selected.

The first base material may be formed of only one layer (single layer), or may be formed of a plurality of layers of two or more layers. When the first base material is formed of a plurality of layers, the plurality of layers may be the same or different from each other, and a combination of the plurality of layers is not particularly limited.

The thickness of the first base material is preferably from 5 to 1000 μm, more preferably from 10 to 500 μm, still more preferably from 15 to 300 μm, and particularly preferably from 20 to 150 μm.

Here, the “thickness of the first base material” means the thickness of the entire first base material, and for example, the thickness of the first base material formed of a plurality of layers means the total thickness of all layers constituting the first base material.

The first base material is preferably one having high thickness accuracy, that is, one in which variation in thickness is suppressed regardless of the site. Among the constituent materials described above, examples of the material that can be used to form the first base material having such high thickness accuracy include a polyethylene, a polyolefin other than polyethylene, a polyethylene terephthalate, and an ethylene-vinyl acetate copolymer.

The first base material may contain various known additives such as a filler, a colorant, an antistatic agent, an antioxidant, an organic lubricant, a catalyst, and a softener (plasticizer) in addition to the main constituent material such as the resin.

The first base material may be transparent or opaque, may be colored according to the purpose, or may have another layer deposited thereon.

When the first protective membrane forming film is energy ray-curable, the first base material preferably transmits energy rays.

The first base material can be manufactured by a known method. For example, the first base material containing a resin can be produced by molding a resin composition containing the resin.

### Example of First Protective Membrane Forming Sheet

A preferable example of the first protective membrane forming sheet of the present embodiment is a first protective membrane forming sheet for forming a first protective membrane at least on a surface of a semiconductor wafer having a bump,
the first protective membrane forming sheet including the first base material, the buffer layer, the intermediate release layer, and the first protective membrane forming film stacked in this order in a thickness direction thereof,
in which
the intermediate release layer contains an ethylene-vinyl acetate copolymer, and a proportion of a content of the ethylene-vinyl acetate copolymer to a total mass of the intermediate release layer in the intermediate release layer is 80 mass % or more,
the first protective membrane forming film is the thermosetting first protective membrane forming film containing the polymer component (A), the thermosetting component (B), the curing accelerator (C), the filler (D), and the additive (I), and a proportion of a total content of the polymer component (A), the thermosetting component (B), the curing accelerator (C), the filler (D), and the additive (I) to a total mass of the first protective membrane forming film in the first protective membrane forming film is 85 mass % or more, and
the buffer layer is produced using a composition for forming the buffer layer containing the urethane (meth)acrylate (X), the thiol group-containing compound (Y), the polymerizable monomer (Z), the photopolymerization initiator, and the cross-linking agent, and a proportion of a total content of the urethane (meth)acrylate (X), the thiol group-containing compound (Y), the polymerizable monomer (Z), the photopolymerization initiator, and the cross-linking agent to a total content of components other than a solvent in the composition for forming the buffer layer is 85 mass % or more.

In such a first protective membrane forming sheet, the thickness of the first protective membrane forming film is preferably from 2 to 7 times the thickness of the intermediate release layer, and the thickness of the buffer layer is preferably from 10 to 70 times the thickness of the intermediate release layer.

Another preferred example of the first protective membrane forming sheet of the present embodiment is a first protective membrane forming sheet for forming a first protective membrane at least on a surface of a semiconductor wafer having a bump,
the first protective membrane forming sheet including the first base material, the buffer layer, the intermediate release layer, and the first protective membrane forming film stacked in this order in a thickness direction thereof,
wherein
the intermediate release layer contains an ethylene-vinyl acetate copolymer, and a proportion of a content of the ethylene-vinyl acetate copolymer to a total mass of the intermediate release layer in the intermediate release layer is 80 mass % or more, a proportion of an amount of a constitutional unit derived from vinyl acetate to a total amount of constitutional units in the ethylene-vinyl acetate copolymer is from 16 to 40 mass %, and a weight average molecular weight of the ethylene-vinyl acetate copolymer is 200000 or less,
the first protective membrane forming film is a thermosetting first protective membrane forming film containing the polymer component (A), the thermosetting component (B), the curing accelerator (C), the filler (D), and the additive (I), the polymer component (A) is polyvinyl acetal, the thermosetting component (B) is the epoxy resin (B1) and the thermal curing agent (B2), the additive (I) is one or two or more selected from the group consisting of a rheology control agent, a surfactant, and a silicone oil, and a proportion of a total content of the polymer component (A), the thermosetting component (B), the curing accelerator (C), the filler (D), and the additive (I) to a total mass of the first protective membrane forming film in the first protective membrane forming film is 85 mass % or more, and
the buffer layer is produced using the composition for forming the buffer layer containing the urethane (meth)acrylate (X), the thiol group-containing compound (Y), the polymerizable monomer (Z), the photopolymerization initiator, and the cross-linking agent, wherein the urethane (meth)acrylate (X) is a reaction product of a terminal isocyanate urethane prepolymer, which is a reaction product of the polyol compound (x1) and the polyisocyanate compound (x2), and the compound (x3) having a (meth)acryloyl group, the thiol group-containing compound (Y) is a polyfunctional thiol group-containing compound having two or more thiol groups per molecule thereof, and the polymerizable monomer (Z) is a (meth)acrylate having an alicyclic structure and a (meth)acrylate having a functional group, and a proportion of a total content of the urethane (meth)acrylate (X), the thiol group-containing compound (Y), the polymerizable monomer (Z), the photopolymerization initiator, and the cross-linking agent to a total content of components other than a solvent in the composition for forming the buffer layer is 85 mass % or more.

In such a first protective membrane forming sheet, the thickness of the first protective membrane forming film is preferably from 2 to 7 times the thickness of the intermediate release layer, and the thickness of the buffer layer is preferably from 10 to 70 times the thickness of the intermediate release layer.

### Method for Manufacturing First Protective Membrane Forming Sheet

The first protective membrane forming sheet can be manufactured by sequentially stacking the above-described layers so as to have a corresponding positional relationship. The method for forming each layer is as described above.

For example, the first protective membrane forming sheet can be manufactured by the following method.

That is, the buffer layer is formed on the first base material by coating the composition for forming the buffer layer (for example, the composition (VI)) onto one surface of the first base material and drying the buffer layer as necessary. When the composition for forming the buffer layer has energy ray curability, the coated composition for forming the buffer layer is further cured with energy rays. This makes it possible to produce a first stacked sheet in which the first base material and the buffer layer are stacked. A release film may be further provided on the exposed surface of the buffer layer in the first stacked sheet (the surface opposite to the first base material side) as necessary.

Separately, the intermediate release layer is formed on the release film by coating the composition for forming the intermediate release layer (for example, the composition (VII)) onto the release film, and drying as necessary. At this time, the composition for forming the intermediate release layer is preferably coated onto the release treatment surface of the release film.

Separately, the first protective membrane forming film is formed on the release film by coating the composition for forming the first protective membrane (for example, the composition (III), the composition (IV), or the composition (V)) onto the release film, and drying as necessary. At this time, the composition for forming the first protective membrane is preferably coated onto the release treatment surface of the release film.

Next, the exposed surface of the buffer layer (the surface on the side opposite to the first base material side) and the exposed surface of the intermediate release layer (the surface on the side opposite to the release film side) in the first stacked sheet are bonded to each other. This makes it possible to produce a second stacked sheet in which the first base material, the buffer layer, the intermediate release layer, and the release film are stacked in this order in the thickness direction thereof.

Next, in the second stacked sheet, the release film is removed, and the exposed surface (surface opposite to the buffer layer side) of the intermediate release layer and the exposed surface (surface opposite to the release film side) of the first protective membrane forming film, which are generated by the removal, are bonded to each other. This makes it possible to produce the first protective membrane forming sheet in which the first base material, the buffer layer, the intermediate release layer, the first protective membrane forming film, and the release film are stacked in this order in the thickness direction. The release film provided on the first protective membrane forming film in the first protective membrane forming sheet may be removed at any stage from the production to the completion of the use of the first protective membrane forming sheet.

The first protective membrane forming sheet including another layer other than the above-described layers can be manufactured by appropriately adding any one or both of the step of forming the another layer and the step of stacking the another layer so that the staking position of the another layer becomes an appropriate position in the above-described manufacturing method.

### Method for Manufacturing Semiconductor Device (Method for Using First Protective Membrane Forming Sheet)

As described above, by using the first protective membrane forming sheet of the present embodiment, attaching the first protective membrane forming film therein to the bump-formed surface of a semiconductor wafer, and then curing the first protective membrane forming film as necessary, a semiconductor wafer with the first protective membrane including the semiconductor wafer and the first protective membrane provided on the bump-formed surface of the semiconductor wafer can be manufactured. At this time, the first protective membrane forming sheet of the present embodiment can be attached to the bump-formed surface of the semiconductor wafer at a high speed. Further, even when such a first protective membrane forming sheet is attached at a high speed, it is possible to cause the top portion of the bump to protrude from the first protective membrane forming film and to prevent the first protective membrane forming film from remaining on the upper portion of the bump. Next, the semiconductor wafer with the first protective membrane is divided, whereby a semiconductor chip with the first protective membrane including the semiconductor chip and the first protective membrane provided on a bump-formed surface of the semiconductor chip can be manufactured. At this time, since the first protective membrane forming film is prevented from remaining on the upper portion of the bump of the semiconductor wafer with the first protective membrane, the attachment of the first protective membrane is also prevented on the upper portion of the bump of the resulting semiconductor chip with the first protective membrane. Further, the semiconductor device can be manufactured by flip-chip connecting the semiconductor chip with the first protective membrane to the substrate in the bump therein. At this time, since the attachment of the first protective membrane on the upper portion of the bump of the semiconductor chip with the first protective membrane is prevented, the electrical connection between the semiconductor chip and the substrate is not interrupted. That is, the first protective membrane forming sheet of the present embodiment is suitable for manufacturing a semiconductor device.

Hereinafter, a method for manufacturing a semiconductor device when the first protective membrane forming sheet is used will be described.

A method for manufacturing a semiconductor device according to one embodiment of the present invention is a method for manufacturing a semiconductor device using the first protective membrane forming sheet, the method including:
attaching the first protective membrane forming film in the first protective membrane forming sheet to a surface of a semiconductor wafer having a bump (bump-formed surface) such that a top portion of the bump protrudes from the first protective membrane forming film to provide the first protective membrane forming sheet on the semiconductor wafer;
forming a first protective membrane by removing a layer other than the first protective membrane forming film from the first protective membrane forming film in the first protective membrane forming sheet after the attaching of the first protective membrane forming film, and further, in a case where the first protective membrane forming film is curable, curing the first protective membrane forming film to form a first protective membrane, or in a case where the first protective membrane forming film is non-curable, handling as the first protective membrane, the first protective membrane from which the layer other than the first protective membrane forming film has been removed to form the first protective membrane on the surface having the bump (bump-formed surface);
dividing the semiconductor wafer after the forming of the first protective membrane to produce a semiconductor chip;
cutting the first protective membrane after the forming of the first protective membrane; and
mounting the semiconductor chip with the first protective membrane to a substrate by flip-chip connecting the semiconductor chip with the first protective membrane to the substrate at a top portion of the bump, the semiconductor chip with the first protective membrane including the semiconductor chip produced after the dividing of the semiconductor and the cutting of the first protective membrane, and the first protective membrane provided on a surface of the semiconductor chip having the bump, wherein the top portion of the bump protrudes from the first protective membrane.

Among methods for manufacturing a semiconductor device according to the present embodiment, a method in a case where the first protective membrane forming film is curable (in the present specification, the method may be referred to as “manufacturing method (1)”) includes:
attaching the first protective membrane forming film in the first protective membrane forming sheet to a surface of a semiconductor wafer having a bump (bump-formed surface) such that a top portion of the bump protrudes from the first protective membrane forming film to provide the first protective membrane forming sheet on the semiconductor wafer;
forming the first protective membrane on the surface having the bump (bump-formed surface) by removing a layer other than the first protective membrane forming film from the first protective membrane forming film in the first protective membrane forming sheet after the attaching of the first protective membrane forming film, and further curing the first protective membrane forming film to form a first protective membrane;
dividing the semiconductor wafer after the forming of the first protective membrane to produce a semiconductor chip;
cutting the first protective membrane after the forming of the first protective membrane; and
mounting the semiconductor chip with the first protective membrane to a substrate by flip-chip connecting the semiconductor chip with the first protective membrane to the substrate at a top portion of the bump, the semiconductor chip with the first protective membrane including the semiconductor chip produced after the dividing of the semiconductor and the cutting of the first protective membrane, and the first protective membrane provided on a surface of the semiconductor chip having the bump, wherein the top portion of the bump protrudes from the first protective membrane.

Among methods for manufacturing a semiconductor device according to the present embodiment, a method in a case where the first protective membrane forming film is non-curable (in the present specification, the method may be referred to as “manufacturing method (2)”) includes:
attaching the first protective membrane forming film in the first protective membrane forming sheet to a surface of a semiconductor wafer having a bump (bump-formed surface) such that a top portion of the bump protrudes from the first protective membrane forming film to provide the first protective membrane forming sheet on the semiconductor wafer;
forming the first protective membrane on the surface having the bump (bump-formed surface) by removing a layer other than the first protective membrane forming film from the first protective membrane forming film in the first protective membrane forming sheet after the attaching of the first protective membrane forming film, and further handling, as the first protective membrane, the first protective membrane forming film from which the layer other than the first protective membrane forming film has been removed;
dividing the semiconductor wafer after the forming of the first protective membrane to produce a semiconductor chip;
cutting the first protective membrane after forming of the first protective membrane; and
mounting a semiconductor chip with the first protective membrane to a substrate by flip-chip connecting the semiconductor chip with the first protective membrane to the substrate at a top portion of the bump, the semiconductor chip with the first protective membrane including the semiconductor chip produced after the dividing of the semiconductor and the cutting of the first protective membrane, and the first protective membrane provided on a surface of the semiconductor chip having the bump, wherein the top portion of the bump protrudes from the first protective membrane.

### <<Manufacturing Method (1)>>

Hereinafter, the manufacturing method (1) will be described.

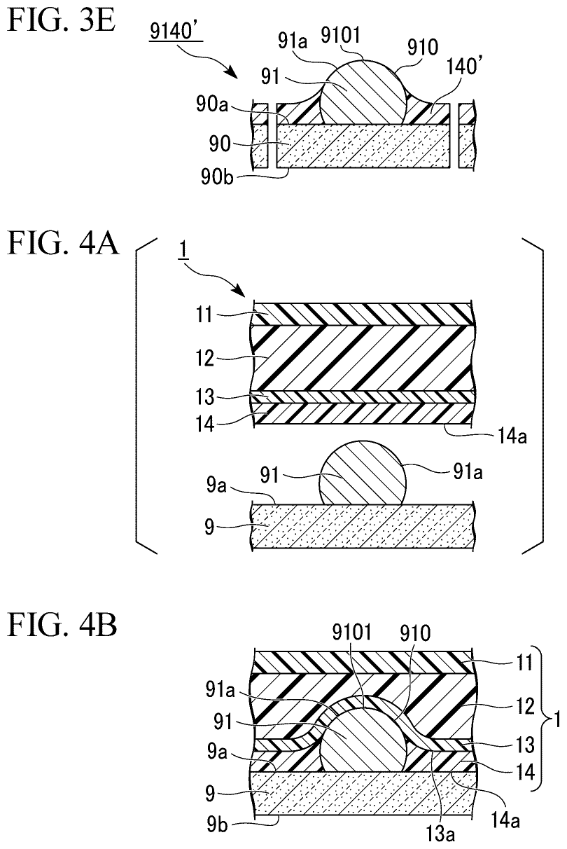

FIGS. 3A to 3E are cross-sectional views for schematically describing an example of the manufacturing method (1) in the case of using the first protective membrane forming sheet 1 illustrated in FIG. 2.

In FIG. 3A and subsequent drawings, the same components as those illustrated in the already described drawings are denoted by the same reference numerals as those in the already described drawings, and a detailed description thereof will be omitted.

### <Attaching of First Protective Membrane Forming Film>

In the attaching of the first protective membrane forming film of the manufacturing method (1), as illustrated in FIGS. 3A to 3B, the first protective membrane forming film 14 in the first protective membrane forming sheet 1 is attached to a surface (bump-formed surface) 9a of a semiconductor wafer 9 having a bump 91, and a top portion 9101 of the bump 91 is caused to protrude from the first protective membrane forming film 14, whereby the first protective membrane forming sheet 1 is provided on the semiconductor wafer 9.

In the attaching of the first protective membrane forming film, for example, first, as illustrated in FIG. 3A, the first protective membrane forming sheet 1 is disposed such that the first protective membrane forming film 14 therein faces the bump-formed surface 9a of the semiconductor wafer 9.

The height of the bump 91 is not particularly limited, but is preferably from 120 to 300 μm, more preferably from 150 to 270 μm, and particularly preferably from 180 to 240 μm. When the height of the bump 91 is more than or equal to the lower limit value, the function of the bump 91 can be further improved. When the height of the bump 91 is less than or equal to the upper limit value, the effect of preventing the first protective membrane forming film 14 from remaining on the upper portion 910 of the bump 91 is further enhanced.

In the present specification, the “height of the bump” means a height at a portion of the bump present at the highest position from the bump-formed surface.

The width of the bump 91 is not particularly limited, but is preferably from 170 to 350 μm, more preferably from 200 to 320 μm, and particularly preferably from 230 to 290 μm. When the width of the bump 91 is larger than or equal to the lower limit value, the function of the bump 91 can be further improved. When the width of the bump 91 is less than or equal to the upper limit value, the effect of preventing the first protective membrane forming film 14 from remaining on the upper portion 910 of the bump 91 is further enhanced.

In the present specification, the “width of the bump” means the maximum value of the length of a line segment formed by connecting two different points on the bump surface with a straight line when the bump is viewed from a direction perpendicular to the bump-formed surface in plan view.

The distance between the adjacent bumps 91 is not particularly limited, but is preferably from 250 to 800 μm, more preferably from 300 to 600 μm, and particularly preferably from 350 to 500 μm. When the distance is more than or equal to the lower limit value, the function of the bump 91 can be further improved. When the distance is less than or equal to the upper limit value, the effect of preventing the first protective membrane forming film 14 from remaining on the upper portion 910 of the bump 91 is further enhanced.

In the present specification, the “distance between the adjacent bumps” means the minimum value of the distance between the surfaces of the adjacent bumps.

Next, in the attaching of the first protective membrane forming film, the first protective membrane forming film 14 is brought into contact with the bump 91 on the semiconductor wafer 9, and the first protective membrane forming sheet 1 is pressed against the semiconductor wafer 9. This causes the first surface 14a of the first protective membrane forming film 14 to be sequentially pressure-bonded to the surface 91a of the bump 91 and the bump-formed surface 9a of the semiconductor wafer 9. At this time, through heating of the first protective membrane forming film 14, the first protective membrane forming film 14 is softened, is spread between the bump 91 and its adjacent bump 91 so as to cover the bump 91, has close contact to the bump-formed surface 9a, and covers the surface 91a of the bump 91, in particular, the surface 91a in the vicinity of the bump-formed surface 9a to embed the base of the bump 91.

Through this, as illustrated in FIG. 3B, the first protective membrane forming film 14 in the first protective membrane forming sheet 1 is attached to the bump-formed surface 9a of the semiconductor wafer 9.

As described above, as a method of pressure-bonding (in other words, attaching) the first protective membrane forming sheet 1 to the semiconductor wafer 9, a known method of pressure-bonding and attaching various sheets to an object can be applied, and examples thereof include a method using a roller type laminator.

The heating temperature of the first protective membrane forming sheet 1 (first protective membrane forming film 14) at the time of pressure-bonding (attaching) to the semiconductor wafer 9 may be a temperature at which curing of the thermosetting first protective membrane forming film 14 does not proceed at all or excessively, and it may be, for example, from 80 to 100° C.

However, the heating temperature is more preferably from 85 to 95° C. in that the effect of preventing the first protective membrane forming film 14 from remaining on the upper portion 910 of the bump 91 is further enhanced.

The pressure at the time of pressure-bonding (attaching) the first protective membrane forming sheet 1 (first protective membrane forming film 14) to the semiconductor wafer 9 is not particularly limited, and it may be, for example, from 0.1 to 1.5 MPa.

However, the pressure is more preferably from 0.3 to 1 MPa in that the effect of preventing the first protective membrane forming film 14 from remaining on the upper portion 910 of the bump 91 is further enhanced.

The speed (attachment speed) at the time of attaching the first protective membrane forming sheet 1 (first protective membrane forming film 14) to the semiconductor wafer 9 may be, for example, 3 mm/s or more, but is preferably 4 mm/s or more. That is, in the attaching of the first protective membrane forming film, the first protective membrane forming film 14 is preferably attached to the bump-formed surface 9a of the semiconductor wafer 9 at an attachment speed of 4 mm/s or more. Attaching the first protective membrane forming film 14 at a high speed such as 4 mm/s or more causes the above-described effect of preventing the first protective membrane forming film 14 from remaining on the upper portion 910 of the bump 91 to be exhibited more remarkably. On the other hand, when the attachment speed is 20 mm/s or less, the above-described effect of preventing the first protective membrane forming film 14 from remaining on the upper portion 910 of the bump 91 is exhibited more stably.

When the first protective membrane forming sheet 1 is pressure-bonded (attached) to the semiconductor wafer 9 like this, pressure is applied from the bump 91 to the first protective membrane forming film 14 and the intermediate release layer 13 in the first protective membrane forming sheet 1 by pushing through the buffer layer 12, and initially, the first surface 14a of the first protective membrane forming film 14 and the first surface 13a of the intermediate release layer 13 are deformed into a recessed shape. Then, the first protective membrane forming film 14 to which pressure is applied from the bump 91 in this state is broken. Finally, in a stage where the first surface 14a of the first protective membrane forming film 14 is pressure-bonded to the bump-formed surface 9a of the semiconductor wafer 9, the upper portion 910 including the top portion 9101 of the bump 91 protrudes through the first protective membrane forming film 14. In this final stage, the upper portion 910 of the bump 91 does not normally penetrate the intermediate release layer 13. This is because the intermediate release layer 13 contains EVA.

As illustrated in FIG. 3B, when the attaching of the first protective membrane forming film is completed, the first protective membrane forming film 14 does not remain at all or substantially in the upper portion 910 including the top portion 9101 of the bump 91, and the first protective membrane forming film 14 is prevented from remaining at the upper portion 910 of the bump 91. In the present specification, the phrase “the first protective membrane forming film does not substantially remain on the upper portion of the bump” means, unless otherwise specified, that although the first protective membrane forming film slightly remains on the upper portion of the bump, the remaining amount is an amount that does not interrupt electrical connection between the semiconductor chip and the substrate when the semiconductor chip including the bump is flip-chip connected to the substrate.

After the attaching of the first protective membrane forming film of the manufacturing method (1), a surface (back surface) 9b of the semiconductor wafer 9 opposite to the bump-formed surface 9a is further ground, and then a second protective membrane forming sheet (not illustrated) is attached to the back surface 9b as necessary.

### <Forming of First Protective Membrane>

After the attaching of the first protective membrane forming film of the manufacturing method (1), in the forming of the first protective membrane, first, as illustrated in FIG. 3C, layers other than the first protective membrane forming film 14 in the first protective membrane forming sheet is removed from the first protective membrane forming film 14. In the present specification, this in the forming of the first protective membrane may be referred to as “removing”. The layers to be removed here are more specifically the first base material 11, the buffer layer 12, and the intermediate release layer 13. As a result, a semiconductor wafer 914 with the first protective membrane forming film including the semiconductor wafer 9 and the first protective membrane forming film 14 provided on the bump-formed surface 9a of the semiconductor wafer 9 is produced.

The layers other than the first protective membrane forming film 14 can be removed from the first protective membrane forming film 14 by a known method.

In the forming of the first protective membrane of the manufacturing method (1), then, as illustrated in FIG. 3D, the first protective membrane forming film 14 is further cured to form a first protective membrane 14′, whereby the first protective membrane 14′ is formed on the bump-formed surface 9a. In the present specification, this in the forming of the first protective membrane may be referred to as “curing”. This makes it possible to produce a semiconductor wafer 914′ with the first protective membrane including the semiconductor wafer 9 and the first protective membrane 14′ provided on the bump-formed surface 9a of the semiconductor wafer 9.

The first protective membrane forming film 14 is curable, and in this (the curing), when the first protective membrane forming film 14 is a thermosetting film, the first protective membrane forming film 14 is cured by heating, and when the first protective membrane forming film 14 is an energy ray-curable film, the first protective membrane forming film 14 is cured by irradiation with energy rays. The heating condition and the energy ray irradiation condition at this time are as described above.

### <Dividing and Cutting>

After the forming of the first protective membrane of the manufacturing method (1), in the dividing, the semiconductor wafer 9 is divided to manufacture a semiconductor chip 90, and in the cutting, the first protective membrane 14′ is cut. Here, the first protective membrane 14′ after cutting is newly denoted by reference numeral 140′.

Performing the dividing and the cutting makes it possible to produce a semiconductor chip 9140′ with the first protective membrane including the semiconductor chip 90 and a first protective membrane 140′ after cutting (in the present specification, it may be simply referred to as “first protective membrane”) provided on a bump-formed surface (surface having bumps) 90a of the semiconductor chip 90 as illustrated in FIG. 3E.

The dividing and the cutting can be performed by a known method.

The order of performing the dividing and the cutting is not particularly limited, but it is preferable to simultaneously perform the dividing and the cutting or to perform the dividing and the cutting in this order. When the dividing and the cutting are performed in this order, for example, the dividing may be performed by known dicing, and then the cutting may be performed immediately and continuously. The dicing can be performed by providing a dicing sheet (not illustrated) on the back surface (which may be a ground back surface) 9b of the semiconductor wafer 9.

In the cutting, the first protective membrane 14′ is cut along the scheduled division portion or the divided portion (in other words, the outer periphery of the semiconductor chip 90) of the semiconductor wafer 9.

In the semiconductor chip 9140′ with the first protective membrane, the top portion 9101 of the bump 91 protrudes from the first protective membrane 140′, the first protective membrane is not adhered at all or substantially to the upper portion 910 including the top portion 9101 of the bump 91, and the attachment of the first protective membrane on the upper portion 910 of the bump 91 is prevented. In the present specification, “the first protective membrane is not adhered substantially to the upper portion of the bump” means that although the first protective membrane is slightly adhered to the upper portion of the bump, the attachment amount of the first protective membrane is an amount that does not interrupt electrical connection between the semiconductor chip and the substrate when the semiconductor chip including the bump is flip-chip connected to the substrate unless otherwise specified.

### <Mounting>

In the mounting of the manufacturing method (1), the semiconductor chip 9140′ with the first protective membrane in which the top portion 9101 of the bump 91 protrudes from the first protective membrane 140′, produced after the dividing and the cutting, is flip-chip connected (not illustrated) to the substrate at the top portion 9101 of the bump 91. At this time, the semiconductor chip 9140′ with the first protective membrane is connected to the circuit formation surface of the substrate.

In the upper portion 910 of the bump 91 in the semiconductor chip 9140′ with the first protective membrane, since the attachment of the first protective membrane 140′ is prevented, the electrical connectivity between the semiconductor chip 90 and the substrate is high in this connection.

When the sheet for forming the second protective membrane is used, the semiconductor chip 9140′ with the first protective membrane is separated from a dicing sheet (not illustrated) in the sheet for forming the second protective membrane and picked up before flip-chip connection.

The semiconductor chip 9140′ with the first protective membrane can be picked up by a known method.

When the second protective membrane forming sheet is used, the semiconductor chip 90 in the semiconductor chip 9140′ with the first protective membrane includes the second protective membrane after cutting on the back surface 90b (not illustrated).

When the second protective membrane forming film in the second protective membrane forming sheet is curable, the second protective membrane forming film is cured at an appropriate timing according to the type thereof to form the second protective membrane. Then, the second protective membrane is cut at an appropriate timing according to the type thereof.

The second protective membrane forming film can be cured by the same method as in the case of the first protective membrane forming film 14, and it may be cured simultaneously with the first protective membrane forming film 14, or may be cured separately from the first protective membrane forming film 14.

The second protective membrane can be cut by the same method as in the case of the first protective membrane.

The order of performing the dividing and the cutting of the second protective membrane is not particularly limited, but it is preferable that the dividing and the cutting of the second protective membrane are simultaneously performed, or the cutting of the second protective membrane is performed after the dividing. When the dividing and the cutting of the second protective membrane are performed in this order, for example, the dividing may be performed by known dicing, and then the cutting of the second protective membrane may be performed continuously and immediately.

The second protective membrane is cut along the scheduled division portion or the divided portion (in other words, the outer periphery of the semiconductor chip 90) of the semiconductor wafer 9.

Thereafter, a semiconductor package is produced according to a known method using the circuit board thus produced on which the semiconductor chip 90 is mounted, and an intended semiconductor device can be manufactured by using this semiconductor package (not illustrated).

### <<Manufacturing Method (2)>>

Next, a manufacturing method (2) will be described.

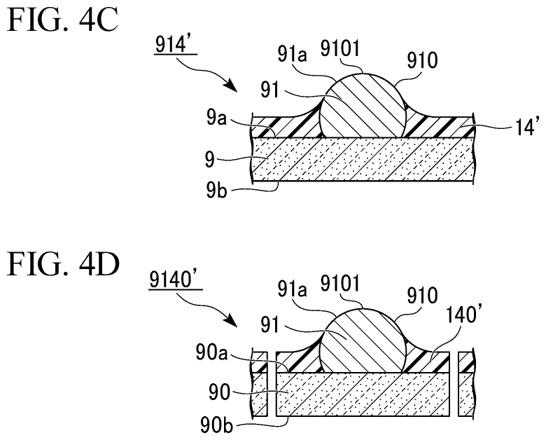

FIGS. 4A to 4D are cross-sectional views for schematically describing an example of the manufacturing method (2) in the case of using the first protective membrane forming sheet 1 illustrated in FIG. 2.

In the attaching of the first protective membrane forming film of the manufacturing method (2), as illustrated in FIGS. 4A to 4B, the first protective membrane forming film 14 in the first protective membrane forming sheet 1 is attached to the a surface (bump-formed surface) 9a of a semiconductor wafer 9 having a bump 91, and a top portion 9101 of the bump 91 is caused to protrude from the first protective membrane forming film 14, whereby the first protective membrane forming sheet 1 is provided on the semiconductor wafer 9.

The attaching of the first protective membrane forming film of the manufacturing method (2) is the same as the attaching of the first protective membrane forming film of the manufacturing method (1) except that the first protective membrane forming film 14 in the protective membrane forming sheet 1 is not curable but non-curable, and can be performed in the same manner as the attaching of the first protective membrane forming film of the manufacturing method (1). Thus, further detailed description of the attaching of the first protective membrane forming film of the manufacturing method (2) is omitted.

Also in the manufacturing method (2), as illustrated in FIG. 4B, when the attaching of the first protective membrane forming film is completed, the first protective membrane forming film 14 does not remain at all or substantially in the upper portion 910 including the top portion 9101 of the bump 91, and the first protective membrane forming film 14 is prevented from remaining at the upper portion 910 of the bump 91 even when the first protective membrane forming film 14 is attached to the bump-formed surface 9a of the semiconductor wafer 9 at high speed.

After the attaching of the first protective membrane forming film of the manufacturing method (2), a surface (back surface) 9b of the semiconductor wafer 9 opposite to the bump-formed surface 9a is further ground, and then a second protective membrane forming sheet (not illustrated) is attached to the back surface 9b as necessary.

### <Forming of First Protective Membrane>

After the attaching of the first protective membrane forming film of the manufacturing method (2), in the forming of the first protective membrane, layers other than the first protective membrane forming film 14 in the first protective membrane forming sheet 1 are removed from the first protective membrane forming film 14. In the present specification, as in the case of the manufacturing method (1), this forming of the first protective membrane may be referred to as “removing”. This (removing) is the same as the removing in the manufacturing method (1) described above except that the first protective membrane forming film 14 in the protective membrane forming sheet 1 is not curable but non-curable, and can be performed in the same manner as the removing in the manufacturing method (1). Thus, further detailed description of the removing in the manufacturing method (2) will be omitted.

In the forming of the first protective membrane of the manufacturing method (2), the non-curable first protective membrane forming film 14 after removing the layers other than the first protective membrane forming film 14 is handled as the first protective membrane. As a result, as illustrated in FIG. 4C, the first protective membrane 14′ is formed on the bump-formed surface 9a.

The non-curable first protective membrane forming film 14 also functions as a protective membrane in this state. Thus, in the present embodiment, the non-curable first protective membrane forming film 14 is regarded as the first protective membrane 14′ after the intermediate release layer 13 is removed at the time of use.

This makes it possible to produce the semiconductor wafer 914′ with the first protective membrane as in the case after the curing of the manufacturing method (1).

Also in the manufacturing method (2), in the semiconductor chip 9140′ with the first protective membrane, the top portion 9101 of the bump 91 protrudes from the first protective membrane 140′, the first protective membrane is not adhered at all or substantially to the upper portion 910 including the top portion 9101 of the bump 91, and the attachment of the first protective membrane on the upper portion 910 of the bump 91 is prevented.

### <Dividing and Cutting>

After the forming of the first protective membrane of the manufacturing method (1), in the dividing, the semiconductor wafer 9 is divided to manufacture a semiconductor chip 90, and in the cutting, the first protective membrane 14′ is cut.

Performing the dividing and the cutting makes it possible to produce the semiconductor chip 9140′ with the first protective membrane as illustrated in FIG. 4D.

The dividing and the cutting of the manufacturing method (2) are the same as the dividing and the cutting of the manufacturing method (1) except that the first protective membrane 14′ is not a cured product of the first protective membrane forming film 14, and can be performed in the same manner as the dividing and the cutting of the manufacturing method (1). Thus, further detailed description of the dividing and the cutting of the manufacturing method (2) will be omitted.

### <Mounting>

In the mounting of the manufacturing method (2), the semiconductor chip 9140′ with the first protective membrane in which the top portion 9101 of the bump 91 protrudes from the first protective membrane 140′, produced after the dividing and the cutting, is flip-chip connected (not illustrated) to the substrate at the top portion 9101 of the bump 91. At this time, the semiconductor chip 9140′ with the first protective membrane is connected to the circuit formation surface of the substrate.

In the upper portion 910 of the bump 91 in the semiconductor chip 9140′ with the first protective membrane, since the attachment of the first protective membrane 140′ is prevented, the electrical connectivity between the semiconductor chip 90 and the substrate is high in this connection.

The mounting of the manufacturing method (2) are the same as the mounting of the manufacturing method (1) except that the first protective membrane 140′ is not a cured product of the first protective membrane forming film 14, and can be performed in the same manner as the mounting of the manufacturing method (1). Thus, further detailed description of the mounting of the manufacturing method (2) is omitted.

Also in the manufacturing method (2), hereinafter, by the same method as in the manufacturing method (1), a semiconductor package is produced using a circuit board on which the semiconductor chip 90 has been mounted, and the intended semiconductor device can be manufactured by using this semiconductor package (not illustrated).

In both of the manufacturing method (1) and the manufacturing method (2), the case where the first protective membrane forming sheet 1 illustrated in FIG. 2 is used has been described, but even when a first protective membrane forming sheet of another embodiment is used, this first protective membrane forming sheet has the same effect as the case where the first protective membrane forming sheet 1 is used.

### <<Modification of Method for Manufacturing Semiconductor Device (Method of Using First Protective Membrane Forming Sheet)>>

In the method for manufacturing a semiconductor device according to the present embodiment, a semiconductor wafer in which a groove to be a division portion of the semiconductor wafer when the semiconductor wafer is divided into individual semiconductor chips is formed on the bump-formed surface can be used as the semiconductor wafer. Such a semiconductor wafer makes it possible to manufacture a semiconductor chip in which the first protective membrane is provided not only on the bump-formed surface but also on a side surface. Here, the side surface means an outer periphery of the semiconductor chip which is continuous with the bump-formed surface, and the semiconductor chip having a rectangular planar shape has four side surfaces. Then, in the semiconductor chip having a rectangular planar shape, the first protective membrane is provided on the bump-formed surface and the four side surfaces. Regardless of the planar shape of the semiconductor chip, the semiconductor chip in which the side surface is also protected as described above can achieve a higher protective effect by the first protective membrane.

A method for manufacturing a semiconductor device according to the present embodiment in this case is, for example, the method for manufacturing a semiconductor device using the first protective membrane forming sheet according to one embodiment of the present invention described above, the method using, as a semiconductor wafer, a semiconductor wafer including a groove to be a division portion of the semiconductor wafer on a surface having a bump (bump-formed surface), the method including:
attaching the first protective membrane forming film in the first protective membrane forming sheet to the surface of the semiconductor wafer having the bump (bump-formed surface) such that a top portion of the bump protrudes from the first protective membrane forming film, the groove is filled with the first protective membrane forming film, to provide the first protective membrane forming sheet on the semiconductor wafer;
forming a first protective membrane by removing a layer other than the first protective membrane forming film from the first protective membrane forming film in the first protective membrane forming sheet after the attaching of the first protective membrane forming film, and further, in a case where the first protective membrane forming film is curable, curing the first protective membrane forming film to form a first protective membrane, or in a case where the first protective membrane forming film is non-curable, handling, as the first protective membrane, the first protective membrane after the layer other than the first protective membrane forming film has been removed to form the first protective membrane on the surface having the bump (bump-formed surface);
dividing the semiconductor wafer, after the forming of the first protective membrane, by grinding a surface (back surface) opposite to the surface of the semiconductor wafer having the bump (bump-formed surface) such that a ground surface reaches the groove filled with the first protective membrane (the groove appears at the opposite surface) to produce a semiconductor chip group integrated due to the first protective membrane filled in the groove;
cutting the first protective membrane after the dividing; and
mounting the semiconductor chip with the first protective membrane to a substrate by flip-chip connecting the semiconductor chip with the first protective membrane to the substrate at a top portion of the bump, the semiconductor chip with the first protective membrane including the semiconductor chip produced after the dividing and the cutting, and the first protective membrane provided on a surface of the semiconductor chip having the bump and a side surface, wherein the top portion of the bump protrudes from the first protective membrane.

Among the modifications of the method for manufacturing a semiconductor device according to the present embodiment, a method in a case where the first protective membrane forming film is curable (in the present specification, the method may be referred to as “manufacturing method (3)”) uses, as a semiconductor wafer, a semiconductor wafer including a groove to be a division portion of the semiconductor wafer on the surface of the semiconductor wafer having a bump (bump-formed surface), the method including:
attaching the first protective membrane forming film in the first protective membrane forming sheet to the surface of the semiconductor wafer having the bump (bump-formed surface) such that a top portion of the bump protrudes from the first protective membrane forming film, and the groove is filled with the first protective membrane forming film, to provide the first protective membrane forming sheet on the semiconductor wafer;
forming a first protective membrane by removing a layer other than the first protective membrane forming film from the first protective membrane forming film in the first protective membrane forming sheet after the attaching the first protective membrane forming film, and further curing the first protective membrane forming film to form a first protective membrane;
dividing the semiconductor wafer, after the forming of the first protective membrane, by grinding a surface (back surface) opposite to the surface of the semiconductor wafer having the bump (bump-formed surface) such that a ground surface reaches the groove filled with the first protective membrane (the groove appears at the opposite surface) to produce a semiconductor chip group integrated due to the first protective membrane filled in the groove;
cutting the first protective membrane after the dividing; and
mounting the semiconductor chip with the first protective membrane to a substrate by flip-chip connecting the semiconductor chip with the first protective membrane to the substrate at a top portion of the bump, the semiconductor chip with the first protective membrane including the semiconductor chip produced after the dividing and the cutting, and the first protective membrane provided on a surface of the semiconductor chip having the bump and a side surface, wherein the top portion of the bump protrudes from the first protective membrane.

In the modification of the method for manufacturing a semiconductor device according to the present embodiment, a method in a case where the first protective membrane forming film is non-curable (in the present specification, the method may be referred to as “manufacturing method (4)”) uses, as a semiconductor wafer, a semiconductor wafer including a groove to be a division portion of the semiconductor wafer on the surface of the semiconductor wafer having a bump (bump-formed surface), the method including:
attaching the first protective membrane forming film in the first protective membrane forming sheet to the surface of the semiconductor wafer having the bump (bump-formed surface) such that a top portion of the bump protrudes from the first protective membrane forming film, and the groove is filled with the first protective membrane forming film, to provide the first protective membrane forming sheet on the semiconductor wafer;
forming of a first protective membrane by removing a layer other than the first protective membrane forming film from the first protective membrane forming film in the first protective membrane forming sheet after the attaching of the first protective membrane forming film, and handling, as the first protective membrane, the first protective membrane from which the layer other than the first protective membrane forming film has been removed to form the first protective membrane on the surface having the bump (bump-formed surface);
dividing the semiconductor wafer, after the forming of the first protective membrane, by grinding a surface (back surface) opposite to the surface of the semiconductor wafer having the bump (bump-formed surface) such that a ground surface reaches the groove filled with the first protective membrane (the groove appears at the opposite surface) to produce a semiconductor chip group integrated due to the first protective membrane filled in the groove;
cutting the first protective membrane after the dividing; and
mounting the semiconductor chip with the first protective membrane to a substrate by flip-chip connecting the semiconductor chip with the first protective membrane to the substrate at a top portion of the bump, the semiconductor chip with the first protective membrane including the semiconductor chip produced after the dividing and the cutting, and the first protective membrane provided on a surface of the semiconductor chip having the bump and a side surface, wherein the top portion of the bump protrudes from the first protective membrane.

The attaching of the first protective membrane forming film of the above-described modifications (the manufacturing method (3) and the manufacturing method (4)) can be performed in the same manner as in the case of the attaching of the first protective membrane forming film of the manufacturing method (the manufacturing method (1) and the manufacturing method (2)) using the semiconductor wafer in which the groove is not formed except that the semiconductor wafer in which the groove is further formed on the bump-formed surface is used as the semiconductor wafer.

The forming of the first protective membrane forming of the above-described modifications (manufacturing method (3) and manufacturing method (4)) can be performed in the same manner as in the case of the forming of the first protective membrane of the manufacturing method (manufacturing method (1) and manufacturing method (2)) using the semiconductor wafer on which the groove is not formed.

The dividing of the above-described modifications (manufacturing method (3) and manufacturing method (4)) can be performed in the same manner as in the case of the dividing of the manufacturing method (manufacturing method (1) and manufacturing method (2)) using the semiconductor wafer on which the groove is not formed except that the method of dividing the semiconductor wafer is limited to a specific method of grinding the back surface of the semiconductor wafer.

The cutting of the above-described modifications (manufacturing method (3) and manufacturing method (4)) can be performed, for example, by attaching a dicing sheet to a surface (back surface) of all semiconductor chips on a surface (back surface) opposite to the surface having the bump (bump-formed surface), and then cutting the first protective membrane filled in the groove along the side surface of the semiconductor chip at a portion near the center in the width direction of the groove. By doing so, the first protective membrane is cut between the side surfaces of the adjacent semiconductor chips, and a semiconductor chip in a state where the first protective membrane is provided on these side surfaces is produced. The cutting of the first protective membrane at this time can be performed by a known method.

The mounting of the above-described modifications (manufacturing method (3) and manufacturing method (4)) can be performed in the same manner as in the case of the mounting of the manufacturing method (manufacturing method (1) and manufacturing method (2)) using the semiconductor wafer on which the groove is not formed.

### EXAMPLES

Hereinafter, the present invention will be described in further detail with reference to specific examples. However, the present invention is in no way limited to the examples described below.

### <Raw Material for Manufacturing Composition for Forming First Protective Membrane>

Raw materials used for manufacturing the composition for forming the first protective membrane are listed below.

### [Polymer Component (A)]

(A)-1: poly(vinyl butyral) having constitutional units represented by Formulas (i)-1, (i)-2, and (i)-3 below (“S-LEC BL-10” available from Sekisui Chemical Co., Ltd., weight average molecular weight 25000, glass transition temperature 59° C.).

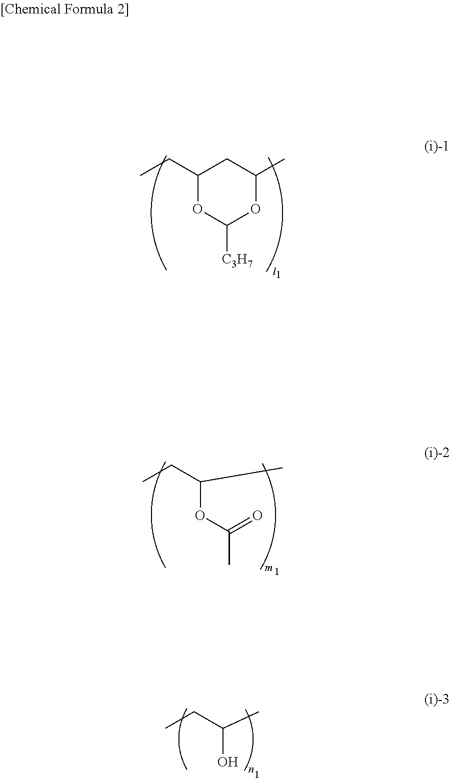

(In the formulae, l₁ is approximately 28, m₁ is from 1 to 3, and n₁ is an integer from 68 to 74.)

### [Epoxy Resin (B1)]

(B1)-1: liquid bisphenol A-type epoxy resin (“EPICLON EXA-4850-150” available from DIC Corporation, molecular weight 900, epoxy equivalent weight 450 g/eq)
(B1)-2: dicyclopentadiene-type epoxy resin (“Epiclon HP-7200HH” available from DIC Corporation, epoxy equivalent weight 254 to 264 g/eq)

### [Thermal Curing Agent (B2)]

(B2)-1: O-cresol-type novolac resin (“PHENOLITE KA-1160” available from DIC Corporation)

### [Curing Accelerator (C)]

(C)-1: 2-phenyl-4,5-dihydroxymethylimidazole (“CUREZOL 2PHZ-PW” available from Shikoku Chemicals Corporation)

### [Filler (D)]

(D)-1: spherical silica modified with an epoxy group (“ADMANANO YA050C-MKK” available from Admatechs Company Limited, average particle size 50 nm)

### [Additive (I)]

(I)-1: a surfactant (acrylic polymer, “BYK-361N” available from BYK)
(I)-2: a silicone oil (aralkyl-modified silicone oil, “XF42-334” available from Momentive Performance Materials Japan LLC)

### Example 1

### <<Production of First Protective Membrane Forming Sheet>>

### <Production of Composition for Forming Thermosetting First Protective Membrane>

The polymer component (A)-1 (100 parts by mass), the epoxy resin (B1)-1 (290 parts by mass), the epoxy resin (B1)-2 (220 parts by mass), the epoxy resin (B2)-1 (160 parts by mass), the curing accelerator (C)-1 (2 parts by mass), the filler (D)-1 (200 parts by mass), the additive (I)-1 (25 parts by mass), and the additive (I)-2 (3 parts by mass) were dissolved or dispersed in methyl ethyl ketone, and stirred at 23° C. to produce the composition (III) in which the total concentration of all components other than the solvent was 45 mass %, as a composition for forming a thermosetting first protective membrane. The blended amount of each of the components other than the solvent shown here is the blended amount of the target product containing no solvent.

### <Production of First Protective Membrane Forming Film>

Using a release film (“SP-PET 381031” manufactured by Lintec Corporation, thickness: 38 μm) in which one surface of a polyethylene terephthalate film was subjected to a release treatment by a silicone treatment, the composition (III) produced above was coated to the release-treated surface, and dried by heating at 120° C. for 2 minutes to form a first protective membrane forming film having a thickness of 45 μm.

### <Production of Composition for Forming Buffer Layer>

A monofunctional urethane acrylate (40 parts by mass), isobornyl acrylate (45 parts by mass), 2-hydroxypropyl acrylate (15 parts by mass), pentaerythritol tetrakis (3-mercaptobutyrate) (“Karenz MT (trade name) PE1” manufactured by Showa Denko K.K., secondary tetrafunctional thiol group-containing compound, solid content concentration: 100 mass %) (3.5 parts by mass), a cross-linking agent (1.8 parts by mass), and a photopolymerization initiator (2-hydroxy-2-methyl-1-phenyl-propane-1-one, “DAROCURE (trade name) 1173” manufactured by BASF SE, solid content concentration: 100 mass %) (1.0 parts by mass) were blended to produce the composition (VI).

### <Formation of Buffer Layer>

A PET film (“COSMOSHINE (trade name) A4300” manufactured by Toyobo Co., Ltd., thickness: 75 μm) was used as the first base material, and the composition (VI) produced above was coated onto one surface of the first base material to form a coating membrane. The coating membrane was irradiated with ultraviolet rays from the outside on the exposed surface side (side opposite to the PET-based film side) to form a half-cured product of the coating membrane. At this time, an ultraviolet ray having a wavelength of 365 nm was used for irradiation under conditions of an illuminance of 120 mW/cm² and a light amount of 200 mJ/cm² using a belt conveyor type ultraviolet ray irradiating device (“ECS-401 GGX” manufactured by EYE GRAPHICS CO., LTD.) as an ultraviolet ray irradiating device and a high pressure mercury lamp (“H04-L 41” manufactured by EYE GRAPHICS CO., LTD.) as an ultraviolet ray source. These irradiation conditions were specified using an ultraviolet integrated illuminometer (“UVPF-A1” manufactured by EYE GRAPHICS CO., LTD.).

Next, the release-treated surface of the release film (“SP-PET 381031” manufactured by Lintec Corporation, thickness: 38 μm) was bonded to the exposed surface of the produced half-cured product to prepare a stack, and the stack was irradiated with ultraviolet rays from the outside on the release film side to completely cure the half-cured product, thereby forming a buffer layer having a thickness of 400 μm. At this time, an ultraviolet ray having a wavelength of 365 nm was irradiated under conditions of an illuminance of 330 mW/cm² and a light amount of 1200 mJ/cm² using the same ultraviolet irradiating device and ultraviolet ray source as described above. These irradiation conditions were specified using the same ultraviolet integrated illuminometer as described above.

In this manner, a stacked sheet (corresponding to the first stacked sheet) was produced in which the first base material, the buffer layer, and the release film were stacked in this order in the thickness direction thereof.

### <Production of Composition for Forming Intermediate Release Layer>

An ethylene-vinyl acetate copolymer (EVA, weight average molecular weight 55000, VA content 20 mass %) was dissolved in toluene at normal temperature to prepare a toluene solution having a solid content concentration of 12 mass %, and this solution was used as the composition (VII).

### <Formation of Intermediate Release Layer>

The composition (VII) produced above was coated to the release-treated surface of the release film (“SP-PET 381031” manufactured by Lintec Corporation, thickness: 38 μm), and dried by heating at 100° C. for 2 minutes to form an intermediate release layer having a thickness of 10 μm.

### <Production of First Protective Membrane Forming Sheet>

In the stacked sheet (first stacked sheet) provided with a buffer layer produced as described above, the release film was removed, and the exposed surface of the intermediate release layer produced as described above was bonded to the exposed surface of the buffer layer generated by the removal to produce a stacked sheet (corresponding to the second stacked sheet) in which the intermediate release layer was further stacked. Next, the release film was removed from the intermediate release layer (in the second stacked sheet) after the bonding, and the exposed surface of the first protective membrane forming film produced above was bonded to the exposed surface of the intermediate release layer generated by the removal.

In this manner, a first protective membrane forming sheet was produced in which the first base material (thickness: 75 μm), the buffer layer (thickness: 400 μm), the intermediate release layer (thickness: 10 μm), and the first protective membrane forming film (thickness: 45 μm) were stacked in this order in the thickness direction.

### <<Evaluation of First Protective Membrane Forming Sheet>>

### <<Evaluation of High-Speed Attachment Property of First Protective Membrane Forming Sheet>>

The exposed surface (surface opposite to the intermediate release layer side) of the first protective membrane forming film in the first protective membrane forming sheet produced above was pressure-bonded to the bump-formed surface of the semiconductor wafer having a bump and a diameter of 8 inches, whereby the first protective membrane forming sheet was attached to the bump-formed surface of the semiconductor wafer. At this time, a semiconductor wafer with a height of the bump of 210 μm, a width of the bump of 250 μm, and a distance between the bumps of 400 μm was used. The attachment of the first protective membrane forming sheet was performed by using an attachment device (Roller type laminator, “RAD-3510 F/12” manufactured by Lintec Corporation) under the conditions of a table temperature of 90° C., an attachment pressure of 0.5 MPa, and a roller attachment height—400 μm while heating the first protective membrane forming sheet. Then, such attachment was performed a plurality of times while changing the attachment speed.

Next, the semiconductor wafer to which the first protective membrane forming sheet was attached was observed through the first protective membrane forming sheet using a digital microscope. At this time, in the semiconductor wafer, one place (size of 6 mm×6 mm) in the central portion and four places (size of 6 mm×6 mm) at equal intervals in the vicinity of the outer peripheral portion were selected. At this time, these five places were observed in such a manner that the direction connecting the two places in the vicinity of the outer peripheral portion and the one place in the central portion coincided with the attachment direction of the first protective membrane forming sheet. In each of these five locations, eight bumps are included, that is, the peripheral portions of a total of 40 bumps in the semiconductor wafer are observed. Then, when air bubbles (in other words, a gap portion between the semiconductor wafer and the first protective membrane forming sheet) connected between the adjacent bumps were present at any of these five locations, it was determined that the first protective membrane forming film in the first protective membrane forming sheet was not properly attached to the bump-formed surface of the semiconductor wafer, and the attachment speed of the first protective membrane forming sheet when the first protective membrane forming film was properly attached was confirmed. Then, based on the attachment speed, the high-speed attachment property of the first protective membrane forming sheet was evaluated according to the following criteria. The results are indicated in Table 1.

### [Evaluation Criteria]

A: Proper attachment was possible at an attachment speed of 5 mm/s, and high-speed attachment properties were exhibited.

B: Proper attachment was possible at an attachment speed of 3 mm/s, but normal attachment was not possible at an attachment speed of 5 mm/s, and high-speed attachment properties were not exhibited.

C: Proper attachment cannot be performed at an attachment speed of 3 mm/s, and attachment suitability was not exhibited.

### <Evaluation of Bump Penetrability of First Protective Membrane Forming Film (Confirmation of Thickness of Deposit of First Protective Membrane on Bump)>

The first protective membrane forming sheet was attached to the bump-formed surface of the semiconductor wafer by the same method as in the “Evaluation of high-speed attachment property of first protective membrane forming sheet”. However, the attachment speed was specified to 5 mm/s.

Next, the back surface of the semiconductor wafer was ground using a grinding device (“DFG 8760” manufactured by Disco) to set the thickness of the semiconductor wafer to 250 μm.

Subsequently, the first base material, the buffer layer, and the intermediate release layer were removed from the first protective membrane forming film using a multi-wafer mounter (“RAD-2700 F/12” manufactured by Lintec Corporation) to expose the first protective membrane forming film. Then, the first protective membrane forming film was heated at 130° C. for 4 hours to form a first protective membrane.

Next, a dicing sheet (dicing tape “Adwill D-686H” manufactured by Lintec Corporation) was attached to the back surface (ground surface) of the semiconductor wafer, and the semiconductor wafer was divided into semiconductor chips having a size of 6 mm×6 mm using a blade dicer (“DFD6362” manufactured by Disco Corporation) and a dicing blade (“ZH05-SD2000N1-90CC” manufactured by Disco Corporation) at a rotation speed of the blade of 30000 rpm and a feeding speed of the blade of 30 mm/s, and the first protective membrane was simultaneously cut into the same size.

A group of semiconductor chips with a first protective membrane was thus produced in which a large number (a plurality) of semiconductor chips with a first protective membrane, each including a semiconductor chip and a first protective membrane provided on a bump-formed surface of the semiconductor chip, were aligned and held on a dicing sheet.

In the group of semiconductor chips with the first protective membrane produced as described above, one semiconductor chip with the first protective membrane was selected at one location in the central portion thereof and four locations at equal intervals in the vicinity of the outer peripheral portion thereof, and at this time, five semiconductor chips with the first protective membrane were taken out in total from each of the five locations so that the direction connecting two locations in the vicinity of the outer peripheral portion and one location in the central portion coincided with the attachment direction of the first protective membrane forming sheet.

Next, using a scanning electron microscope (SEM, “VE-9700” manufactured by Keyence Corporation), the surface of the bump of the semiconductor chip with the first protective membrane was observed from a direction perpendicular to the bump-formed surface of the semiconductor chip with the first protective membrane and a direction forming an angle of 60°, and the presence or absence of attachment of the first protective membrane on the upper portion of the bump was confirmed. Each of the five semiconductor chips with the first protective membrane includes eight bumps, that is, the surfaces with a total of 40 bumps were observed. The reason of the observation of the surface of the bump of the semiconductor chip with the first protective membrane from the direction of the angle of 600 described above is that the first protective membrane remaining on the upper portion of the bump is most easily identified by doing so.

Subsequently, these five semiconductor chips with the first protective membrane were each sealed with an epoxy resin, and the sealed product was polished using a polishing sheet until the section of the central portion of the bump therein was visible. The section was observed using a field emission scanning electron microscope (FE-SEM, “S-4700” manufactured by Hitachi High-Technologies Corporation), the thickness of the deposit of the first protective membrane on the bump was measured, and the maximum value thereof was adopted as the thickness of the deposit. The amount (thickness) of the deposit of the first protective membrane on the upper portion of the bump reflects the amount of the residue of the first protective membrane forming film on the upper portion of the bump, and thus serves as an index in evaluating the penetrability of the bump of the first protective membrane forming film. The results are indicated in Table 1.

### <<Production and Evaluation of First Protective Membrane Forming Sheet>>

### Example 2

A first protective membrane forming sheet was produced and evaluated in the same manner as in Example 1 except that an ethylene-vinyl acetate copolymer (EVA, weight average molecular weight: 65000, VA content: 28 mass %) was used instead of the ethylene-vinyl acetate copolymer (EVA, weight average molecular weight: 55000, VA content: 20 mass %) at the time of producing the composition for forming an intermediate release layer (composition (VII)). The results are indicated in Table 1.

### Example 3

A first protective membrane forming sheet was produced and evaluated in the same manner as in Example 1 except that an ethylene-vinyl acetate copolymer (EVA, weight average molecular weight: 150000, VA content: 32 mass %) was used instead of the ethylene-vinyl acetate copolymer (EVA, weight average molecular weight: 55000, VA content: 20 mass %) at the time of producing the composition for forming an intermediate release layer (composition (VII)). The results are indicated in Table 1.

### <<Production of First Protective Membrane Forming Sheet>>

### Comparative Example 1

### <Production of Pressure Sensitive Adhesive Composition>

An acrylic copolymer produced by copolymerizing 2-ethylhexyl acrylate (80 parts by mass) and 2-hydroxyethyl acrylate (20 parts by mass) was used, and 2-isocyanatoethyl methacrylate (“Karenz MOT (trade name)” manufactured by Showa Denko K.K.) was added to the acrylic copolymer so that the addition rate of a constituent unit derived from 2-hydroxyethyl acrylate to the hydroxyl group (100 equivalents) in the acrylic copolymer was 80 equivalents, whereby an acrylic polymer (weight average molecular weight: 800000) was produced.

A liquid was prepared using methyl ethyl ketone by adding 1-hydroxycyclohexylphenyl ketone (photopolymerization initiator, “Irgacure (trade name) 184” manufactured by BASF SE) (3 parts by mass) and trimethylolpropane adduct tolylene diisocyanate (cross-linking agent, “Coronate (trade name) L” manufactured by Tosoh Corporation) (1.1 parts by mass) to the acrylic polymer (100 parts by mass), and the liquid was stirred for 30 minutes to prepare a pressure sensitive adhesive composition in a solution form having a solid content concentration of 20 mass %.

The pressure sensitive adhesive composition produced above was coated to the release-treated surface of the release film (“SP-PET 381031” manufactured by Lintec Corporation, thickness: 38 μm), and dried by heating at 120° C. for 2 minutes to form a pressure sensitive adhesive layer having a thickness of 10 μm.

A first protective membrane forming sheet was produced in the same manner as in Example 1 except that the pressure sensitive adhesive layer produced above was used instead of the intermediate release layer.

### <<Evaluation of First Protective Membrane Forming Sheet>>

The first protective membrane forming sheet produced above was evaluated in the same manner as in Example 1. The results are indicated in Table 1.

TABLE 1

| | | | | | Comparative |
|---|---|---|---|---|---|
| | | Examples | | | Examples |
| | | 1 | 2 | 3 | 1 |
| Main component of | Component name | EVA | EVA | EVA | Acrylic |
| intermediate | | | | | polymer |
| release layer or | VA content (mass %) | 20 | 28 | 32 | 0 |
| pressure sensitive | Weight average | 55000 | 65000 | 150000 | 800000 |
| adhesive layer | molecular weight | | | | |
| Evaluation results | High-speed attachment | A | A | A | B |
| | property | | | | |
| | Thickness (μm) of | 0.1 | 0.25 | 0.4 | 1.3 |
| | deposit on first | | | | |
| | protective membrane on | | | | |
| | upper portion of bump | | | | |

As is apparent from the above results, in Examples 1 to 3, the first protective membrane forming sheet was properly attached to the bump-formed surface of the semiconductor wafer at an attachment speed of 5 mm/s due to the first protective membrane forming film therein, and the first protective membrane forming sheet had a high-speed attachment property. Even when the first protective membrane was attached at such a high speed, the thickness of the deposit on the first protective membrane on the upper portion of the bump was 0.4 μm or less (from 0.1 to 0.4 μm), and the attachment of the first protective membrane on the upper portion of the bump was able to be prevented. That is, in Examples 1 to 3, even when the first protective membrane forming sheet was attached to the bump-formed surface of the semiconductor wafer at a high speed, the top portion of the bump was able to protrude from the protective membrane forming film, and the first protective membrane forming film was able to be prevented from remaining on the upper portion of the bump. In this manner, in Examples 1 to 3, both the high-speed attachment property of the first protective membrane forming sheet and the penetrability of the bump of the first protective membrane forming film were high.

The first protective membrane forming sheet of Examples 1 to 3 included an intermediate release layer containing an ethylene-vinyl acetate copolymer.

From the results of Examples 1 to 3, it was confirmed that the penetrability of the bump of the first protective membrane forming film tended to increase as the VA content of the ethylene-vinyl acetate copolymer decreased and as the weight average molecular weight of the ethylene-vinyl acetate copolymer decreased.

On the other hand, in Comparative Example 1, the first protective membrane forming sheet was property attached to the bump-formed surface of the semiconductor wafer at an attachment speed of 3 mm/s due to the first protective membrane forming film therein, but was not property attached at an attachment speed of 5 min/s, and the first protective membrane forming sheet did not have the high-speed attachment property. Further, when the attachment was performed at an attachment speed of 5 mm/s, the thickness of the deposit of the first protective membrane on the upper portion of the bump was 1.3 μm, and the attachment of the first protective membrane on the upper portion of the bump could not be prevented. That is, in Comparative Example 1, when the first protective membrane forming sheet was attached to the bump-formed surface of the semiconductor wafer at an attachment speed of 5 mm/s, it was not possible to prevent the first protective membrane forming film from remaining on the upper portion the bump. As described above, in Comparative Example 1, the first protective membrane forming sheet did not have a high-speed attachment property, and the first protective membrane forming film had a low bump penetrability.

The first protective membrane forming sheet of Comparative Example 1 included a pressure sensitive adhesive layer containing an acrylic polymer, not an intermediate release layer containing an ethylene-vinyl acetate copolymer.

### INDUSTRIAL APPLICABILITY

The present invention is a semiconductor chip for use in a flip-chip connection method, and can be used for manufacturing a semiconductor chip or the like having a bump and having a protective membrane on a bump-formed surface.

### REFERENCE SIGNS LIST

1 . . . First protective membrane forming sheet, 11 . . . First base material, 12 . . . Buffer layer, 13 . . . Intermediate release layer, 14 . . . First protective membrane forming film, 14′ . . . First protective membrane, 140′ . . . First protective membrane after cutting, 9 . . . Semiconductor wafer, 9a . . . Bump-formed surface of semiconductor wafer (surface of semiconductor wafer having bumps), 90 . . . Semiconductor chip, 90a . . . Bump-formed surface of semiconductor chip (surface of semiconductor chip having bumps), 91 . . . Bump, 9101 . . . Top portion of bump, 9140′ . . . Semiconductor chip with first protective membrane

1. A first protective membrane forming sheet for forming a first protective membrane on at least a surface of a semiconductor wafer having a bump,
the first protective membrane forming sheet comprising a first base material, a buffer layer, an intermediate release layer, and a first protective membrane forming film stacked in this order in a thickness direction thereof,
wherein the intermediate release layer contains an ethylene-vinyl acetate copolymer.

2. The first protective membrane forming sheet according to claim 1, wherein in the ethylene-vinyl acetate copolymer, a proportion of an amount of a constitutional unit derived from vinyl acetate to a total amount of constitutional units is from 16 to 40 mass %.

3. The first protective membrane forming sheet according to claim 1, wherein the ethylene-vinyl acetate copolymer has a weight average molecular weight of 200000 or less.

4. A method for manufacturing a semiconductor device using the first protective membrane forming sheet according to claim 1, the method comprising:
attaching the first protective membrane forming film in the first protective membrane forming sheet to a surface of a semiconductor wafer having a bump such that a top portion of the bump protrudes from the first protective membrane forming film, to provide the first protective membrane forming sheet on the semiconductor wafer;
forming of a first protective membrane by
removing a layer other than the first protective membrane forming film from the first protective membrane forming film in the first protective membrane forming sheet after the attaching of the first protective membrane forming film, and further
in case where the first protective membrane forming film is curable, curing the first protective membrane forming film to form a first protective membrane, or
in case where the first protective membrane forming film is non-curable, handling, as the first protective membrane, the first protective membrane after the layer other than the first protective membrane forming film has been removed to form the first protective membrane on the surface having the bump;
dividing the semiconductor wafer after the forming of the first protective membrane forming to produce a semiconductor chip;
cutting the first protective membrane after the forming of the first protective membrane; and
mounting the semiconductor chip with the first protective membrane to a substrate by flip-chip connecting the semiconductor chip with the first protective membrane to the substrate at a top portion of the bump, the semiconductor chip with the first protective membrane including the semiconductor chip produced after the dividing and the cutting, and the first protective membrane provided on a surface of the semiconductor chip having the bump, wherein the top portion of the bump protrudes from the first protective membrane.

5. The method for manufacturing a semiconductor device according to claim 4, wherein in the attaching of the first protective membrane forming film, the first protective membrane forming film is attached to the surface of the semiconductor wafer having the bump at an attachment speed of 4 mm/s or more.

6. A use of a sheet for forming a first protective membrane on at least a surface of a semiconductor wafer, the surface having a bump,
the sheet comprising a first base material, a buffer layer, an intermediate release layer, and a first protective membrane forming film stacked in this order in a thickness direction of thereof,
wherein the intermediate release layer contains an ethylene-vinyl acetate copolymer.
